(19) United States
(12) Patent Application Publication
(10) Pub. No.: US 2026/0068297 A1
(43) Pub. Date: Mar. 5, 2026

(54) SEMICONDUCTOR DEVICE COMPRISING FIN-SHAPED PATTERN

(71) Applicant: Samsung Electronics Co., Ltd., Suwon-si (KR)

(72) Inventors: Song Jae Lee, Suwon-si (KR); Se Woung Oh, Suwon-si (KR); Min Hyung Kang, Suwon-si (KR)

(21) Appl. No.: 19/201,034

(22) Filed: May 7, 2025

(30) Foreign Application Priority Data
Aug. 28, 2024 (KR) 10-2024-0115718

(51) Int. Cl. H10D 84/83; H10D 84/01

(52) U.S. Cl. CPC H10D 84/8311; H10D 84/0128; H10D 84/832

(57) ABSTRACT

A semiconductor device is provided. The semiconductor device includes a substrate, a first active pattern extending in a first direction on the substrate, a second active pattern extending in the first direction on the substrate, the second active pattern spaced apart from the first active pattern in a second direction intersecting the first direction, a plurality of nanosheets spaced apart from each other in a third direction perpendicular to the first direction and the second direction on the first active pattern, a fin-shaped pattern spaced apart from the plurality of nanosheets in the second direction, the fin-shaped pattern comprising a first portion and a second portion. A gate electrode is extending in the second direction on the first and second active patterns, the gate electrode at least partially surrounding each of the plurality of nanosheets and the fin-shaped pattern.

### CROSS-REFERENCE TO RELATED APPLICATION

This application claims priority from Korean Patent Application No. 10-2024-0115718, filed on Aug. 28, 2024, in the Korean Intellectual Property Office, and all the benefits accruing therefrom under 35 U.S.C. 119, the contents of which in its entirety are herein incorporated by reference.

### FIELD

Various exemplary embodiments relate to a semiconductor device. Specifically, the present disclosure relates to a semiconductor device including a MBCFET™ (Multi-Bridge Channel Field Effect Transistor).

### BACKGROUND

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they are easy to scale. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure provides a semiconductor device that may simplify the fabrication process by simultaneously forming a plurality of nanosheets of a transistor (MBCFET™ (Multi-Bridge Channel Field Effect Transistor)) including a plurality of nanosheets and a fin-shaped pattern of a Fin Field Effect Transistor (FinFET).

The embodiments of the present disclosure are not limited to those mentioned above and other embodiments which are not mentioned may be clearly understood by those skilled in the art from the description below.

According to some embodiments of the present disclosure, there is provided a semiconductor device, comprising a substrate, a first active pattern extending in a first direction on the substrate, a second active pattern extending in the first direction on the substrate, the second active pattern spaced apart from the first active pattern in a second direction intersecting the first direction, a plurality of nanosheets spaced apart from each other in a third direction perpendicular to the first direction and the second direction on the first active pattern, a fin-shaped pattern spaced apart from the plurality of nanosheets in the second direction, the fin-shaped pattern comprising a first portion spaced apart from the second active pattern in the third direction and a second portion in contact with an upper surface of the first portion, wherein a width in the second direction of a bottom surface of the second portion is greater than a width in the second direction of the upper surface of the first portion, and a gate electrode extending in the second direction on the first and second active patterns, the gate electrode at least partially surrounding each of the plurality of nanosheets and the fin-shaped pattern.

According to some embodiments of the present disclosure, there is provided a semiconductor device, comprising a substrate, a first active pattern extending in a first direction on the substrate, a second active pattern extending in the first direction on the substrate, the second active pattern spaced apart from the first active pattern in a second direction intersecting the first direction, a plurality of nanosheets spaced apart from each other in a third direction perpendicular to the first direction and the second direction on the first active pattern, a fin-shaped pattern spaced apart from the second active pattern in the third direction, the fin-shaped pattern spaced apart from the plurality of nanosheets in the second direction, a gate electrode extending in the second direction on the first and second active patterns, the gate electrode at least partially surrounding each of the plurality of nanosheets and the fin-shaped pattern, at least a portion of the gate electrode between an upper surface of the second active pattern and a bottom surface of the fin-shaped pattern, a first gate insulating layer between the gate electrode and the plurality of nanosheets, and a second gate insulating layer between the gate electrode and the fin-shaped pattern, wherein a thickness of the second gate insulating layer is greater than a thickness of the first gate insulating layer.

According to some embodiments of the present disclosure, there is provided a semiconductor device, comprising a substrate, a first active pattern extending in a first direction on the substrate, a second active pattern extending in the first direction on the substrate, the second active pattern spaced apart from the first active pattern in a second direction intersecting the first direction, wherein an upper surface of the second active pattern is lower than an upper surface of the first active pattern in a third direction perpendicular to the first direction and the second direction, a width in the second direction of the second active pattern is the same as a width in the second direction of the first active pattern, a plurality of nanosheets stacked and spaced apart from each other in a third direction on the first active pattern, a fin-shaped pattern spaced apart from the plurality of nanosheets in the second direction, the fin-shaped pattern comprising a first portion spaced apart from the second active pattern in the third direction and a second portion being in contact with an upper surface of the first portion, wherein a width in the second direction of a bottom surface of the second portion being greater than a width in the second direction of the upper surface of the first portion, a first gate electrode extending in the second direction on the first active pattern, the first gate electrode at least partially surrounding the plurality of nanosheets, a second gate electrode extending in the second direction on the second active pattern, the second gate electrode being spaced apart from the first gate electrode in the second direction, the second gate electrode at least partially surrounding the fin-shaped pattern, and at least a portion of the second gate electrode being between the upper surface of the second active pattern and a bottom surface of the fin-shaped pattern, a first gate insulating layer between the first gate electrode and the plurality of nanosheets, and a second gate insulating layer between the second gate electrode and the fin-shaped pattern, wherein a thickness of the second gate insulating layer is greater than a thickness of the first gate insulating layer, wherein a thickness in the third direction of the second portion of the fin-shaped pattern is the same as a thickness in the third direction of an uppermost nanosheet of the plurality of nanosheets, and wherein an upper surface of the fin-shaped pattern is on the same plane as an upper surface of the uppermost nanosheet of the plurality of nanosheets.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan diagram illustrating a semiconductor device according to some exemplary embodiments of the present disclosure;

FIG. 2 is a cross-sectional view taken along the line A-A′ of FIG. 1;

FIG. 3 is a cross-sectional view taken along the line B-B′ of FIG. 1;

FIG. 4 is a cross-sectional view taken along the line C-C′ of FIG. 1;

FIGS. 5 to 38 are intermediate stage diagrams illustrating the fabrication method of a semiconductor device according to some example embodiments of the present disclosure;

FIG. 39 is a cross-sectional view illustrating a semiconductor device according to some example embodiments of the present disclosure;

FIG. 40 is a cross-sectional view illustrating a semiconductor device according to some other example embodiments of the present disclosure;

FIGS. 41 to 45 are intermediate stage diagrams illustrating the fabrication method of the semiconductor device shown in FIG. 40;

FIG. 46 is a layout diagram illustrating a semiconductor device according to yet some other example embodiments of the present disclosure;

FIG. 47 is a cross-sectional view taken along the line D-D′ of FIG. 46;

FIG. 48 is an intermediate stage diagram illustrating the fabrication method of the semiconductor device shown in FIGS. 46 and 47;

FIG. 49 is a cross-sectional view illustrating a semiconductor device according to other example embodiments of the present disclosure; and

FIGS. 50 to 52 are intermediate stage diagrams illustrating the fabrication method of the semiconductor device shown in FIGS. 49.

### DETAILED DESCRIPTION OF THE EMBODIMENTS

Hereinafter, example embodiments will be described with reference to the accompanying drawings. In the drawings, like reference numerals denote like elements, and repeated descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

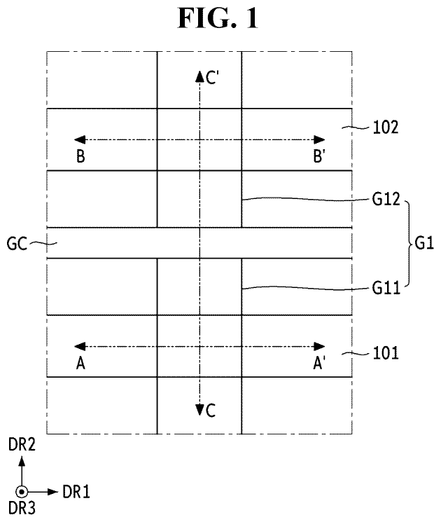

Hereinafter, a semiconductor device according to some example embodiments of the present disclosure will be described with reference to FIGS. 1 to 4.

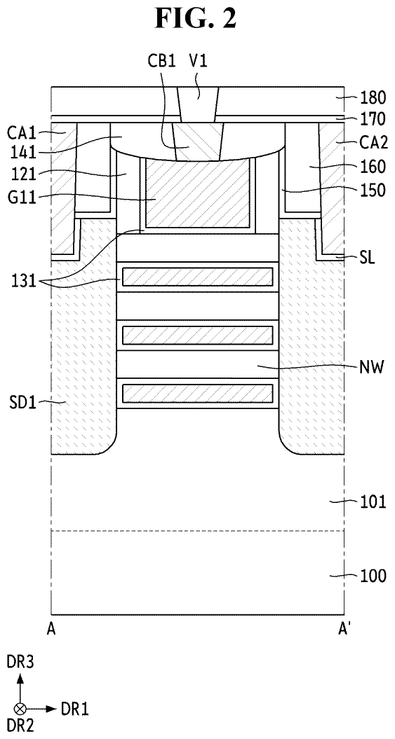

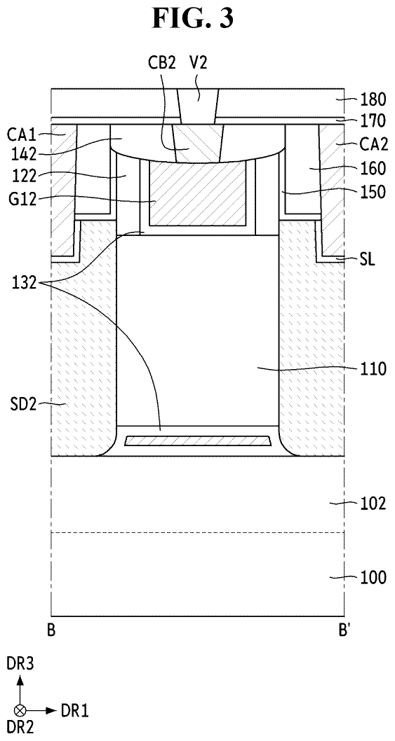

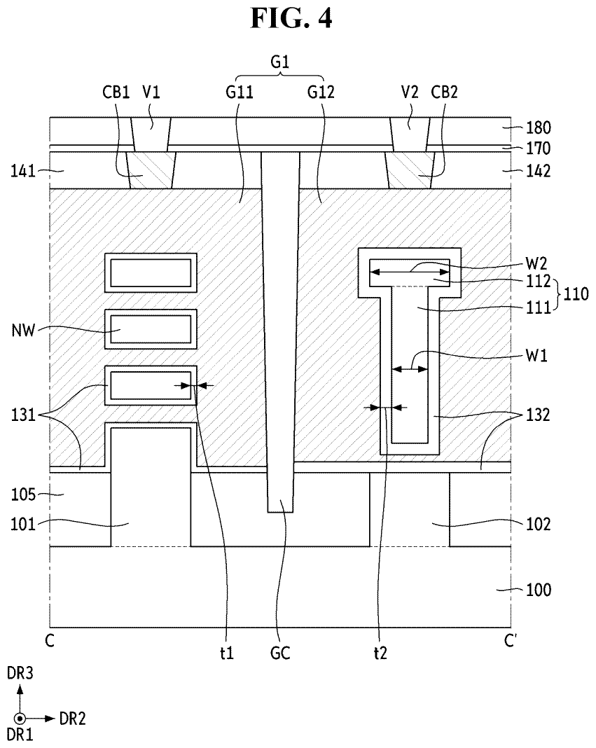

FIG. 1 is a layout or plan diagram for explaining a semiconductor device according to some example embodiments of the present disclosure. FIG. 2 is a cross-sectional view taken along the line A-A′ of FIG. 1. FIG. 3 is a cross-sectional view taken along the line B-B′ of FIG. 1. FIG. 4 is a cross-sectional view taken along the line C-C′ of FIG. 1.

Referring to FIGS. 1 to 4, a semiconductor device according to some example embodiments of the present disclosure includes a substrate 100, first and second active patterns 101, 102, a field insulating layer 105, a plurality of nanosheets NW, a fin-shaped pattern 110, a gate electrode G1, first and second gate spacers 121, 122, first and second gate insulating layers 131, 132, first and second capping patterns 141, 142, first and second source/drain regions SD1, SD2, a first etching stop layer 150, a first interlayer insulating layer 160, a gate cut GC, first and second source/drain contacts CA1, CA2, a silicide layer SL, first and second gate contacts CB1, CB2, a second etching stop layer 170, a second interlayer insulating layer 180, and first and second vias V1, V2.

The substrate 100 may be a silicon substrate or SOI (silicon-on-insulator). Alternatively, the substrate 100 may include silicon germanium, SGOI (silicon germanium on insulator), indium antimonide, lead telluride compounds, indium arsenide, indium phosphide, gallium arsenide, or gallium antimonide, but the present disclosure is not limited thereto. In the following, the first horizontal direction DR1 and the second horizontal direction DR2 may each be defined as directions parallel to an upper surface of the substrate 100. The second horizontal direction DR2 may be defined as a direction different from the first horizontal direction DR1. The vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

Each of the first and second active patterns 101, 102 may extend in the first horizontal direction DR1 on the upper surface of the substrate 100. The second active pattern 102 may be spaced apart from the first active pattern 101 in the second horizontal direction DR2. Each of the first and second active patterns 101, 102 may protrude in the vertical direction DR3 from the upper surface of the substrate 100. For example, each of the first and second active patterns 101, 102 may be part of the substrate 100, or may include an epitaxial layer grown from the substrate 100. For example, the width of the second active pattern 102 in the second horizontal direction DR2 may be the same as the width of the first active pattern 101 in the second horizontal direction DR2. For example, the upper surface of the second active pattern 102 may be formed lower than the upper surface of the first active pattern 101.

The field insulating layer 105 may be disposed on the upper surface of the substrate 100. The field insulating layer 105 may at least partially surround the sidewalls of each of the first and second active patterns 101, 102. For example, the upper surface of the first active pattern 101 may protrude in the vertical direction DR3 beyond the upper surface of the field insulating layer 105. In FIG. 4, the upper surface of the second active pattern 102 is shown to be formed on the same plane as the upper surface of the field insulating layer 105, but the present disclosure is not limited thereto. The field insulating layer 105 may include, for example, an oxide layer, a nitride layer, an oxynitride layer, or a combination thereof.

The plurality of nanosheets NW may be disposed on the upper surface of the first active pattern 101. The plurality of nanosheets NW may be spaced apart from the upper surface of the first active pattern 101 in the vertical direction DR3. The plurality of nanosheets NW may include a plurality of nanosheets stacked and spaced apart from each other in the vertical direction DR3 on the first active pattern 101. In FIGS. 2 to 4, the plurality of nanosheets NW is shown as including three nanosheets stacked and spaced apart from each other in the vertical direction DR3, but this is for the sake of explanation, and the present disclosure is not limited thereto. In other example embodiments, the plurality of nanosheets NW may include four or more nanosheets stacked and spaced apart from each other in the vertical direction DR3. For example, the plurality of nanosheets NW may include silicon (Si).

The fin-shaped pattern 110 may be disposed on the upper surface of the second active pattern 102. The fin-shaped pattern 110 may be spaced apart from the upper surface of the second active pattern 102 in the vertical direction DR3. The fin-shaped pattern 110 may be spaced apart from the plurality of nanosheets NW in the second horizontal direction. The fin-shaped pattern 110 may include a first portion 111 and a second portion 112. The first portion 111 of the fin-shaped pattern 110 may be spaced apart from the upper surface of the second active pattern 102 in the vertical direction DR3. The second portion 112 of the fin-shaped pattern 110 may be in contact with the upper surface of the first portion 111 of the fin-shaped pattern 110. For example, the first portion 111 and the second portion 112 of the fin-shaped pattern 110 may be integrally formed.

For example, the width W2 of the second portion 112 of the fin-shaped pattern 110 in the second horizontal direction DR2 may be greater than the width W1 of the first portion 111 of the fin-shaped pattern 110 in the second horizontal direction DR2. In other words, the width of the bottom surface of the second portion 112 of the fin-shaped pattern 110 in the second horizontal direction DR2 may be greater than the width of the upper surface of the first portion 111 of the fin-shaped pattern 110 in the second horizontal direction DR2. For example, the width W2 of the second portion 112 of the fin-shaped pattern 110 in the second horizontal direction DR2 may be the same as the width of the uppermost nanosheet of the plurality of nanosheets NW in the second horizontal direction DR2. For example, the width W1 of the first portion 111 of the fin-shaped pattern 110 in the second horizontal direction DR2 may be smaller than the width of the plurality of nanosheets NW in the second horizontal direction DR2.

For example, the thickness of the second portion 112 of the fin-shaped pattern 110 in the vertical direction DR3 may be the same as the thickness of the uppermost nanosheet of the plurality of nanosheets NW in the vertical direction DR3. For example, the upper surface of the fin-shaped pattern 110 may be formed on the same plane as the upper surface of the uppermost nanosheet of the plurality of nanosheets NW. In other words, the upper surface of the second portion 112 of the fin-shaped pattern 110 may be formed on the same plane as the upper surface of the uppermost nanosheet of the plurality of nanosheets NW. For example, the fin-shaped pattern 110 may include the same material as the plurality of nanosheets NW. That is, the fin-shaped pattern 110 may be made of silicon (Si).

The gate electrode G1 may extend in the second horizontal direction DR2 on the field insulating layer 105, and the first and second active patterns 101, 102. The gate electrode G1 may at least partially surround each of the plurality of nanosheets NW and the fin-shaped pattern 110. For example, the gate electrode G1 may include a first gate electrode G11 and a second gate electrode G12. The second gate electrode G12 may be spaced apart from the first gate electrode G11 in the second horizontal direction DR2. For example, the first gate electrode G11 may at least partially surround a plurality of nanosheets NW. The second gate electrode G12 may at least partially surround the fin-shaped pattern 110.

For example, at least a portion of the second gate electrode G12 may be disposed between the upper surface of the second active pattern 102 and the bottom surface of the fin-shaped pattern 110. That is, at least a portion of the second gate electrode G12 may be disposed between the upper surface of the second active pattern 102 and the bottom surface of the first portion 111 of the fin-shaped pattern 110. However, the present disclosure is not limited thereto. In some other example embodiments, the second gate electrode G12 may not be disposed between the upper surface of the second active pattern 102 and the bottom surface of the first portion 111 of the fin-shaped pattern 110. For example, the upper surface of the second gate electrode G12 may be formed on the same plane as the upper surface of the first gate electrode G11.

For example, the first gate electrode G11 and the second gate electrode G12 may include the same material. For example, each of the first and second gate electrodes G11, G12 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. Each of the first and second gate electrodes G11, G12 may include a conductive metal oxide, a conductive metal oxynitride, or the like, and may include an oxidized form of the above-described materials.

The first gate spacer 121 may be disposed on both sidewalls of the first gate electrode G11 in the first horizontal direction DR1 on the upper surface of the uppermost nanosheet of the plurality of nanosheets NW and on the upper surface of the field insulating layer 105. The second gate spacer 122 may be disposed on both sidewalls of the second gate electrode G12 in the first horizontal direction DR1 on the upper surface of the second portion 112 of the fin-shaped pattern 110 and on the upper surface of the field insulating layer 105. For example, the second gate spacer 122 may be spaced apart from the first gate spacer 121 in the second horizontal direction DR2. For example, each of the first and second gate spacers 121, 122 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon oxycarbide (SiOC), and/or combinations thereof. However, the present disclosure is not limited thereto.

The first source/drain region SD1 may be disposed on both sidewalls of the plurality of nanosheets NW in the first horizontal direction DR1 on the first active pattern 101. For example, the first source/drain region SD1 may be in contact with both sidewalls of the plurality of nanosheets NW in the first horizontal direction DR1. The second source/drain region SD2 may be disposed on both sidewalls of the fin-shaped pattern 110 in the first horizontal direction DR1 on the second active pattern 102. For example, the second source/drain region SD2 may be in contact with both sidewalls of the fin-shaped pattern 110 in the first horizontal direction DR1. For example, the bottom surface of the second source/drain region SD2 may be formed lower than the bottom surface of the fin-shaped pattern 110. For example, the bottom surface of the second source/drain region SD2 may be formed on the same plane as the bottom surface of the first source/drain region SD1. For example, the upper surface of the second source/drain region SD2 may be formed on the same plane as the upper surface of the first source/drain region SD1.

The first gate insulating layer 131 may be disposed between the first gate electrode G11 and the first gate spacer 121. The first gate insulating layer 131 may be disposed between the first gate electrode G11 and the first active pattern 101. The first gate insulating layer 131 may be disposed between the first gate electrode G11 and the field insulating layer 105. The first gate insulating layer 131 may be disposed between the first gate electrode G11 and a plurality of nanosheets NW. The first gate insulating layer 131 may be disposed between the first gate electrode G11 and the first source/drain region SD1. The second gate insulating layer 132 may be disposed between the second gate electrode G12 and the second gate spacer 122. The second gate insulating layer 132 may be disposed between the second gate electrode G12 and the second active pattern 102. The second gate insulating layer 132 may be disposed between the second gate electrode G12 and the field insulating layer 105. The second gate insulating layer 132 may be disposed between the second gate electrode G12 and the fin-shaped pattern 110. The second gate insulating layer 132 may be disposed between the second gate electrode G12 and the second source/drain region SD2.

For example, at least a portion of the bottom surface of the second portion 112 of the fin-shaped pattern 110 may be in contact with the second gate insulating layer 132. For example, the thickness T2 of the second gate insulating layer 132 may be greater than the thickness T1 of the first gate insulating layer 131. For example, each of the first and second gate insulating layers 131, 132 may include at least one of silicon oxide, silicon oxynitride, silicon nitride, or a high-k dielectric material with a dielectric constant higher than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

In some example embodiments, the semiconductor device may include an NC (Negative Capacitance) FET utilizing a negative capacitor. For example, each of the first and second gate insulating layers 131, 132 may include a ferroelectric material layer exhibiting ferroelectric properties and a paraelectric material layer exhibiting paraelectric properties.

The ferroelectric material layer may have negative capacitance, while the paraelectric material layer may have positive capacitance. For example, when two or more capacitors are connected in series and each of their capacitances has a positive value, the overall capacitance decreases compared to the capacitance of each individual capacitor. On the other hand, when at least one of the capacitances of the two or more capacitors connected in series has a negative value, the overall capacitance may have a positive value and be greater than the absolute value of each individual capacitance.

When the ferroelectric material layer having a negative capacitance and the paraelectric material layer having a positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 m V/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and/or lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). Depending on which ferroelectric material the ferroelectric material layer contains, the type of dopant included in the ferroelectric material layer may vary.

When the ferroelectric material layer includes hafnium oxide, the dopant included in the ferroelectric material layer may include, for example, at least one of gadolinium (Gd), silicon (Si), zirconium (Zr), aluminum (Al), and/or yttrium (Y).

When the dopant is aluminum (Al), the ferroelectric material layer may contain 3 to 8 at % (atomic %) of aluminum. Here, the proportion of the dopant may be a ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and aluminum oxide, but is not limited thereto.

The ferroelectric material layer and the paraelectric material layer may contain the same material. While the ferroelectric material layer has ferroelectric properties, the paraelectric material layer may not have ferroelectric properties. For example, when the ferroelectric material layer and the paraelectric material layer contain hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness for exhibiting ferroelectric properties, the thickness of the ferroelectric material layer may vary depending on the specific ferroelectric material.

For example, each of the first and second gate insulating layers 131, 132 may include a single ferroelectric material layer. In another example, each of the first and second gate insulating layers 131, 132 may include a plurality of ferroelectric material layers spaced apart from each other. Each of the first and second gate insulating layers 131, 132 may have a stacked layer structure in which the plurality of ferroelectric material layers are alternately stacked with the plurality of paraelectric material layers.

The first etching stop layer 150 may be disposed on the sidewalls of each of the first and second gate spacers 121, 122 in the first horizontal direction DR1. The first etching stop layer 150 may be disposed on the upper surfaces of each of the first and second source/drain regions SD1, SD2. Although not shown, the first etching stop layer 150 may be disposed on the upper surface of the field insulating layer 105. Also, although not shown, the first etching stop layer 150 may be disposed on both sidewalls of each of the first and second source/drain regions SD1, SD2 in the second horizontal direction DR2. For example, the first etching stop layer 150 may be conformally formed. For example, the first etching stop layer 150 may include at least one of aluminum oxide, aluminum nitride, hafnium oxide, zirconium oxide, silicon oxide, silicon nitride, silicon oxynitride, and/or a low-k dielectric material.

The first capping pattern 141 may extend in the second horizontal direction DR2 on each of the first gate spacer 121, the first gate insulating layer 131, the first gate electrode G11 and, the first etching stop layer 150. The second capping pattern 142 may extend in the second horizontal direction DR2 on each of the second gate spacer 122, the second gate insulating layer 132, the second gate electrode G12 and the first etching stop layer 150. For example, the second capping pattern 142 may be spaced apart from the first capping pattern 141 in the second horizontal direction DR2. For example, each of the first and second capping patterns 141, 142 may include at least one of silicon nitride (SIN), silicon oxynitride (SiON), silicon oxide (SiO₂) silicon carbonitride (SiCN), silicon oxycarbonitride (SiOCN), and/or combinations thereof. However, the present disclosure is not limited thereto.

The first interlayer insulating layer 160 may be disposed on the first etching stop layer 150. The first interlayer insulating layer 160 may at least partially surround the sidewalls of each of the first and second capping patterns 141, 142. For example, the upper surface of the first interlayer insulating layer 160 may be formed on the same plane as the upper surface of each of the first and second capping patterns 141, 142. For example, the first interlayer insulating layer 160 may include at least one of silicon oxide, silicon nitride, silicon oxynitride, and/or a low-k dielectric material. The low-k dielectric material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, but the present disclosure is not limited thereto.

The gate cut GC may extend in the first horizontal direction DR1 between the first gate electrode G11 and the second gate electrode G12. For example, the gate cut GC may penetrate the gate electrode G1 in the vertical direction DR3. For example, the gate cut GC may extend in the vertical direction DR3 from the inside of the field insulating layer 105. That is, the bottom surface of the gate cut GC may be formed between the bottom surface of the field insulating layer 105 and the upper surface of the field insulating layer 105. For example, the upper surface of the gate cut GC may be formed on the same plane as the upper surfaces of each of the first and second capping patterns 141, 142.

For example, the first gate electrode G11 and the second gate electrode G12 may be separated in the second horizontal direction DR2 through the gate cut GC. For example, the first gate spacer 121 and the second gate spacer 122 may be separated in the second horizontal direction DR2 through the gate cut GC. For example, the first gate insulating layer 131 and the second gate insulating layer 132 may be separated in the second horizontal direction DR2 through the gate cut GC. For example, the first capping pattern 141 and the second capping pattern 142 may be separated in the second horizontal direction DR2 through the gate cut GC. For example, the gate cut GC may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and combinations thereof.

The first source/drain contact CA1 may be disposed on the first side of the gate electrode G1 in the first horizontal direction DR1. The first source/drain contact CA1 may penetrate the first interlayer insulating layer 160 and the first etching stop layer 150 in the vertical direction DR3 and extend into the inside of the first and second source/drain regions SD1, SD2 disposed on the first side of the gate electrode G1. For example, the first source/drain contact CA1 may be electrically connected to each of the first and second source/drain regions SD1, SD2 disposed on the first side of the gate electrode G1. However, the present disclosure is not limited thereto. In some other example embodiments, the first source/drain contact CA1 connected to the first source/drain region SD1 and the first source/drain contact CA1 connected to the second source/drain region SD2 may be separated in the second horizontal direction DR2.

The second source/drain contact CA2 may be disposed on the second side of the gate electrode G1 opposite the first side of the gate electrode G1 in the first horizontal direction DR1. The second source/drain contact CA2 may penetrate the first interlayer insulating layer 160 and the first etching stop layer 150 in the vertical direction DR3 and extend into the inside of the first and second source/drain regions SD1, SD2 disposed on the second side of the gate electrode G1. For example, the second source/drain contact CA2 may be electrically connected to each of the first and second source/drain regions SD1, SD2 disposed on the second side of the gate electrode G1. However, the present disclosure is not limited thereto. In some other example embodiments, the second source/drain contact CA2 connected to the first source/drain region SD1 and the second source/drain contact CA2 connected to the second source/drain region SD2 may be separated in the second horizontal direction DR2.

For example, the upper surfaces of each of the first and second source/drain contacts CA1, CA2 may be formed on the same plane as the upper surface of the first interlayer insulating layer 160. Each of the first and second source/drain contacts CA1, CA2 may include a conductive material. The silicide layer SL may be disposed along the interface between the first source/drain contact CA1 and each of the first and second source/drain regions SD1, SD2. Additionally, the silicide layer SL may be disposed along the interface between the second source/drain contact CA2 and each of the first and second source/drain regions SD1, SD2. For example, the silicide layer SL may include a metal silicide material. The first gate contact CB1 may penetrate the first capping pattern 141 in the vertical direction DR3 to be connected to the first gate electrode G11. The second gate contact CB2 may penetrate the second capping pattern 142 in the vertical direction DR3 to be connected to the second gate electrode G12. Each of the first and second gate contacts CB1, CB2 may include a conductive material.

The second etching stop layer 170 may be disposed on the upper surfaces of each of the first interlayer insulating layer 160, the first and second capping patterns 141, 142, the first and second source/drain contacts CA1, CA2, the first and second gate contacts CB1, CB2, and the gate cut GC. For example, the second etching stop layer 170 may be conformally formed. In FIGS. 2 to 4, the second etching stop layer 170 is shown as being formed as a single layer, but the present disclosure is not limited thereto. In some other example embodiments, the second etching stop layer 170 may be formed as multiple layers. For example, the second etching stop layer 170 may include at least one of aluminum oxide, aluminum nitride, hafnium oxide, zirconium oxide, silicon oxide, silicon nitride, silicon oxynitride, and/or a low-k dielectric material. The second interlayer insulating layer 180 may be disposed on the second etching stop layer 170. For example, the second interlayer insulating layer 180 may include at least one of silicon oxide, silicon nitride, silicon oxynitride, and a low-k dielectric material.

The first via V1 may penetrate the second interlayer insulating layer 180 and the second etching stop layer 170 in the vertical direction DR3 to be connected to the first gate contact CB1. The second via V2 may penetrate the second interlayer insulating layer 180 and the second etching stop layer 170 in the vertical direction DR3 to be connected to the second gate contact CB2. Each of the first and second vias V1, V2 may include a conductive material.

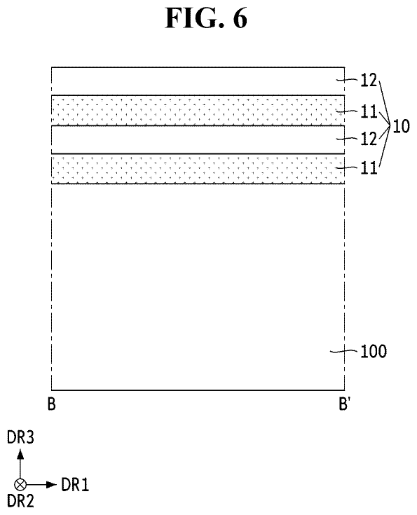

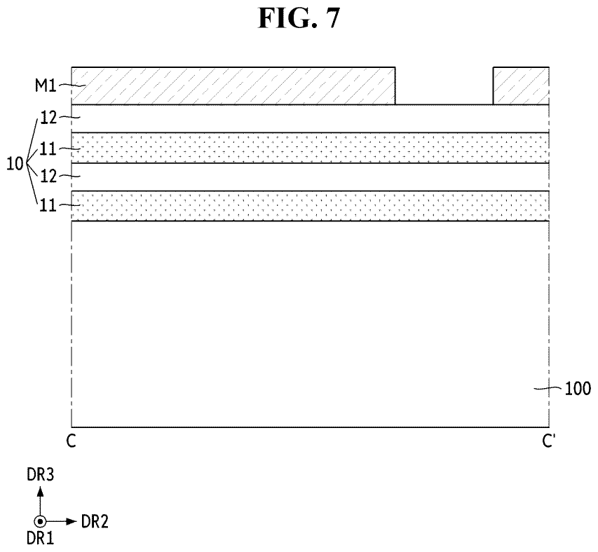

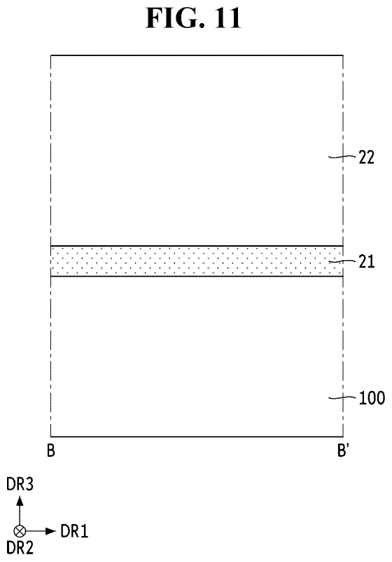

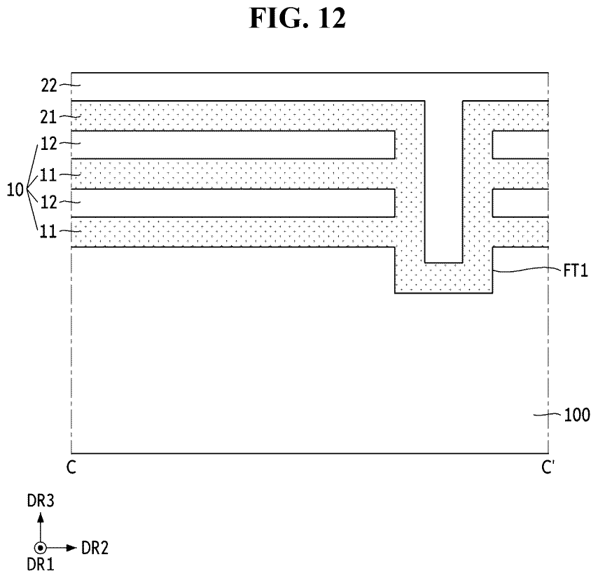

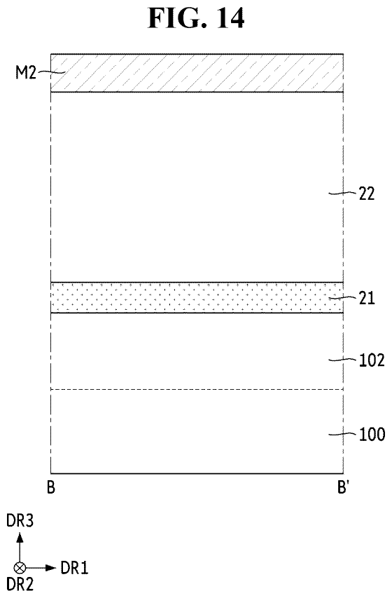

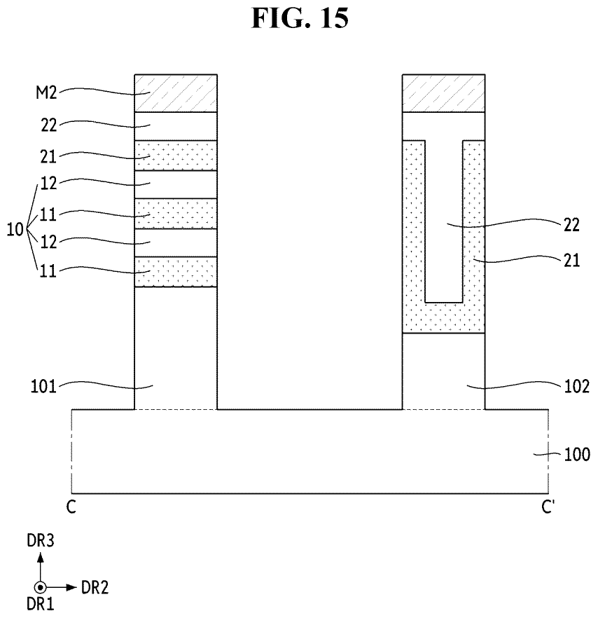

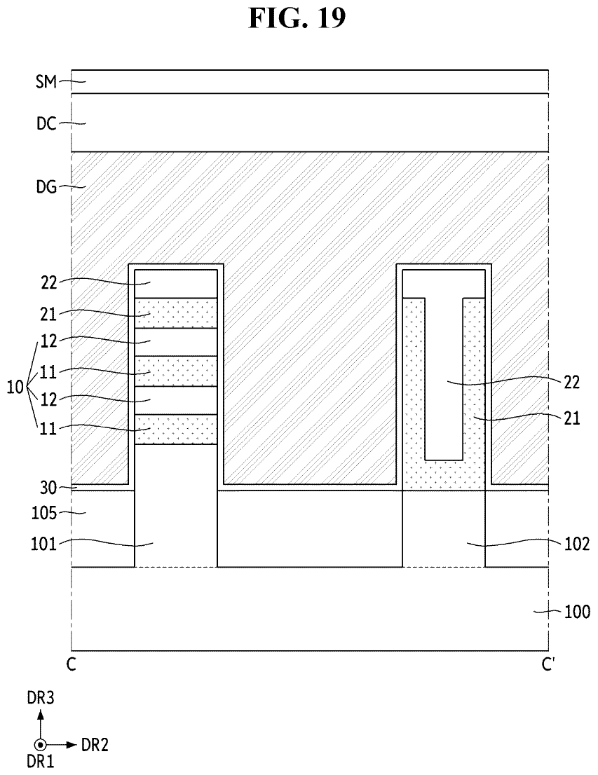

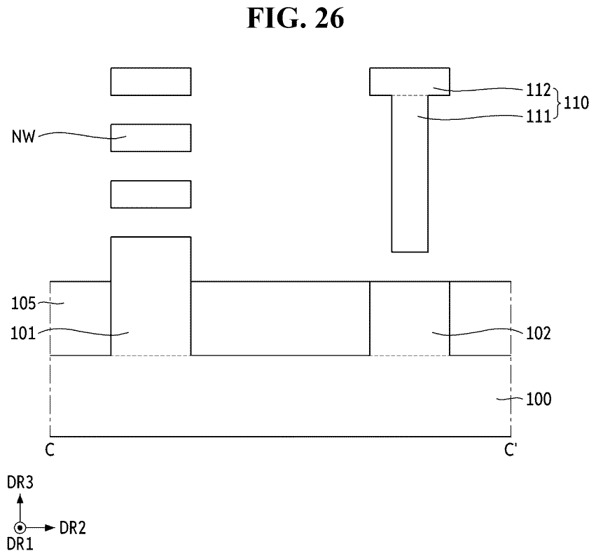

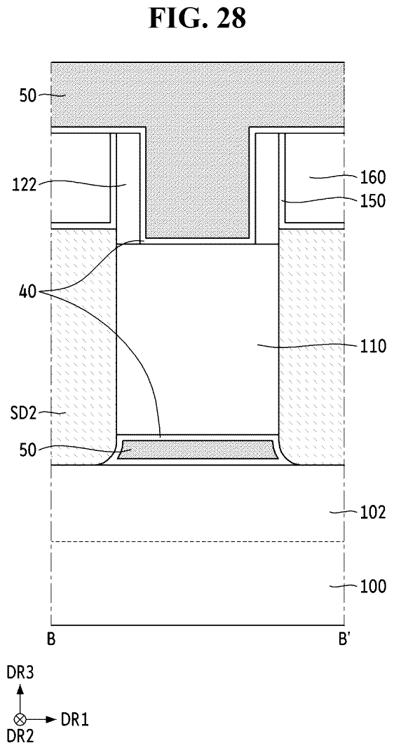

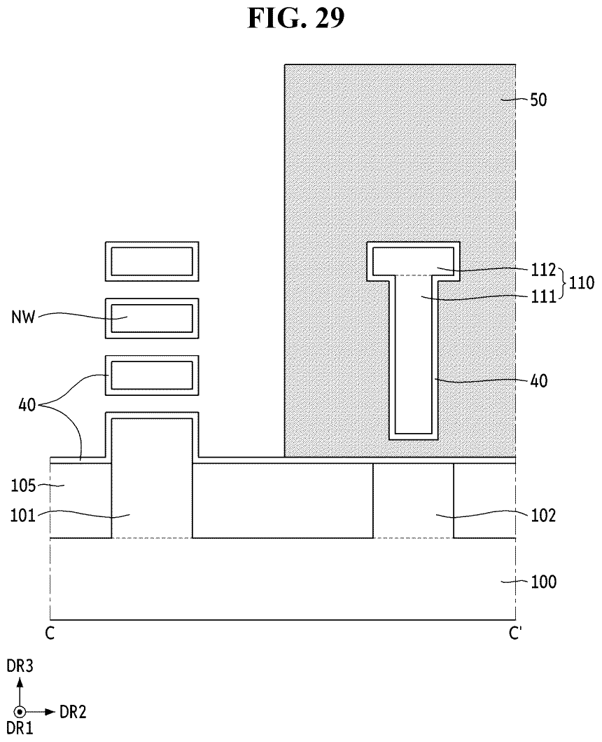

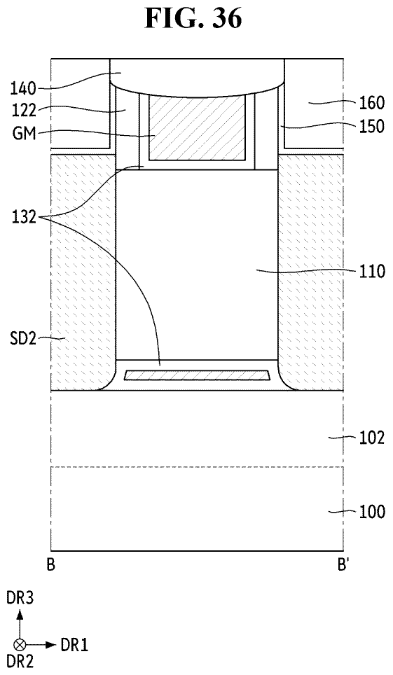

Hereinafter, with reference to FIGS. 2 to 38, the fabrication method of the semiconductor device according to some example embodiments of the present disclosure will be described.

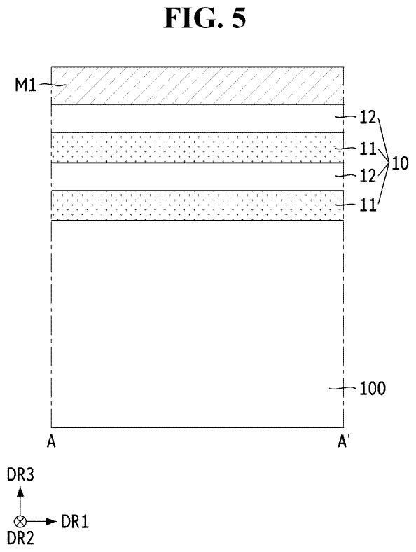

FIGS. 5 to 38 are intermediate stage diagrams for explaining the fabrication method of the semiconductor device according to some example embodiments of the present disclosure.

Referring to FIGS. 5 to 7, a stacked structure 10 may be formed on the substrate 100. The stacked structure 10 may include a first sacrificial layer 11 and a first semiconductor layer 12 alternately stacked on the substrate 100. For example, the first sacrificial layer 11 may be formed at the lowermost portion of the stacked structure 10, and the first semiconductor layer 12 may be formed at the uppermost portion of the stacked structure 10. For example, the first sacrificial layer 11 may include silicon germanium (SiGe). For example, the first semiconductor layer 12 may include silicon (Si). Subsequently, a first mask pattern M1 may be formed on the upper surface of the stacked structure 10.

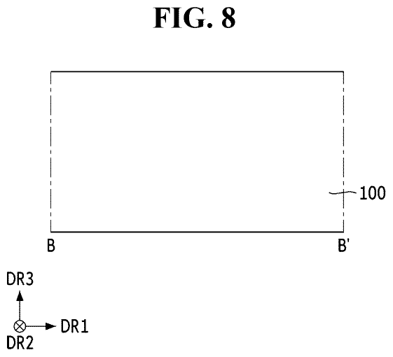

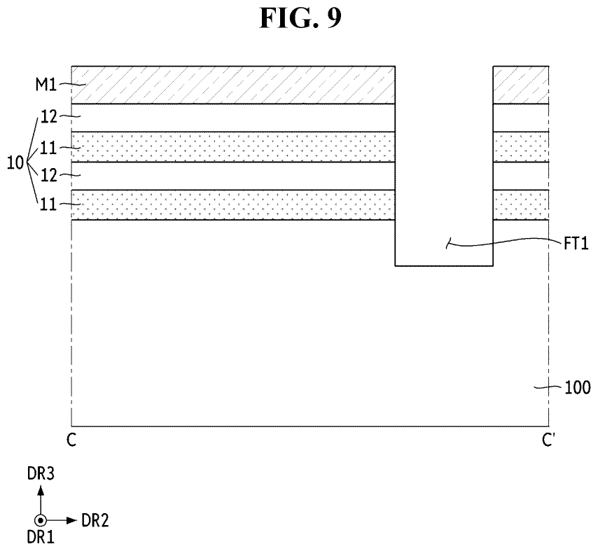

Referring to FIGS. 8 and 9, using the first mask pattern M1 as a mask, a fin trench FT1 may be formed inside the stacked structure 10 by etching the stacked structure 10. For example, the fin trench FT1 may extend into the inside of the substrate 100. That is, the bottom surface of the fin trench FT1 may be formed lower than the bottom surface of the stacked structure 10.

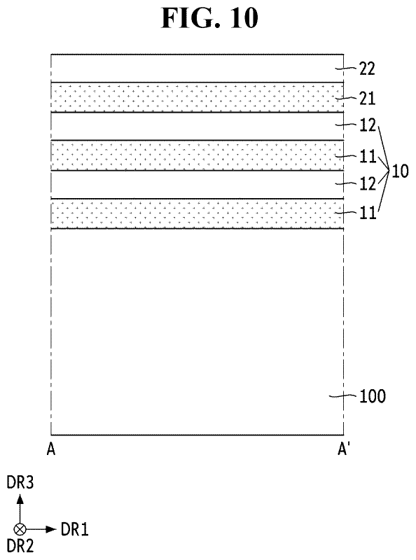

Referring to FIGS. 10 to 12, the first mask pattern M1 (see FIG. 9) may be removed. Subsequently, the second sacrificial layer 21 and the second semiconductor layer 22 may be formed sequentially along the upper surface of the stacked structure 10, the bottom surface and sidewalls of the fin trench FT1. For example, each of the second sacrificial layer 21 and the second semiconductor layer 22 may be conformally formed. For example, the thickness of the second sacrificial layer 21 may be the same as the thickness of the first sacrificial layer 11. Further, the thickness of the second semiconductor layer 22 may be the same as the thickness of the first semiconductor layer 12. However, the present disclosure is not limited thereto.

For example, the fin trench FT1 may be completely filled by the second sacrificial layer 21 and the second semiconductor layer 22. For example, the upper surface of the second semiconductor layer 22 formed on the fin trench FT1 may be formed on the same plane as the upper surface of the second semiconductor layer 22 formed on the stacked structure 10. However, the present disclosure is not limited thereto. In some other example embodiments, at least a portion of the upper surface of the second semiconductor layer 22 formed on the fin trench FT1 may be formed convexly toward the substrate 100. For example, the second sacrificial layer 21 may include silicon germanium (SiGe), and the second semiconductor layer 22 may include silicon (Si).

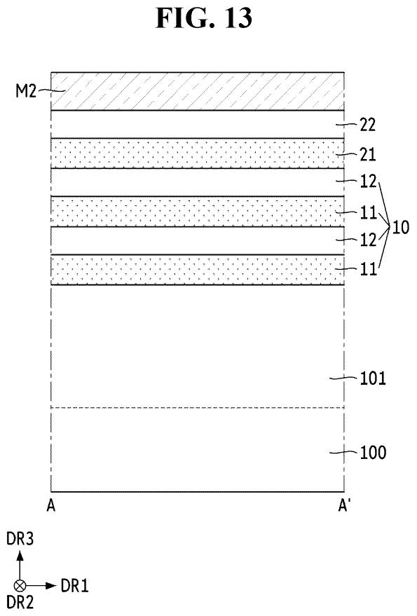

Referring to FIGS. 13 to 15, a second mask pattern M2 may be formed on the second semiconductor layer 22. For example, the second mask pattern M2 may be formed at a portion that overlaps in the vertical direction DR3 with each of the first and second active patterns 101, 102, described later. Subsequently, using the second mask pattern M2 as a mask, the stacked structure 10, the second sacrificial layer 21, and the second semiconductor layer 22 may each be etched. While each of the stacked structure 10, the second sacrificial layer 21, and the second semiconductor layer 22 is being etched, a portion of the substrate 100 may also be etched.

Through this etching process, the first active pattern 101 may be defined beneath the stacked structure 10 on the upper surface of the substrate 100, and the second active pattern 102 may be defined beneath the second sacrificial layer 21 and the second semiconductor layer 22. For example, each of the first and second active patterns 101, 102 may extend in the first horizontal direction DR1. The second active pattern 102 may be spaced apart from the first active pattern 101 in the second horizontal direction DR2. For example, the upper surface of the second active pattern 102 may be formed lower than the upper surface of the first active pattern 101.

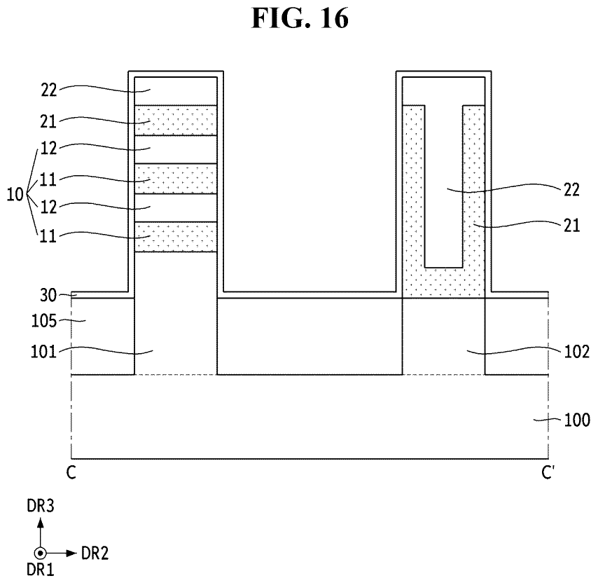

Referring to FIG. 16, the second mask pattern M2 (see FIGS. 13 to 15) may be removed. Subsequently, a field insulating layer 105 may be formed on the upper surface of the substrate 100. The field insulating layer 105 may at least partially surround the sidewalls of each of the first and second active patterns 101, 102. In FIG. 16, the upper surface of the field insulating layer 105 is shown as being formed on the same plane as the upper surface of the second active pattern 102, but the present disclosure is not limited thereto. In some other example embodiments, the upper surface of the field insulating layer 105 may be formed lower than the upper surface of the second active pattern 102. Subsequently, a pad oxide layer 30 may be formed to cover the upper surface of the field insulating layer 105, the exposed sidewalls of the first active pattern 101, the sidewalls of the stacked structure 10, the sidewalls of the second sacrificial layer 21, and the sidewalls and the upper surface of the second semiconductor layer 22. For example, the pad oxide layer 30 may be formed conformally. For example, the pad oxide layer 30 may include silicon oxide (SiO₂).

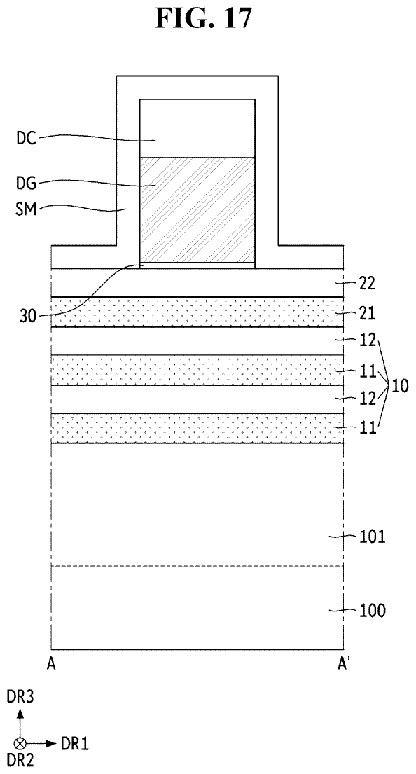

Referring to FIGS. 17 to 19, a dummy gate DG and a dummy capping pattern DC extending in the second horizontal direction DR2 may be formed on the pad oxide layer 30 on the second semiconductor layer 22 and the field insulating layer 105. The dummy capping pattern DC may be disposed on the dummy gate DG. While the dummy gate DG and the dummy capping pattern DC are being formed, the remaining portion of the pad oxide layer 30 except for the portion overlapping with the dummy gate DG in the vertical direction DR3 on the substrate 100, may be removed.

Subsequently, a spacer material layer SM may be formed to cover the sidewalls of the dummy gate DG, the sidewalls and upper surfaces of each of the dummy capping patterns DC, the exposed sidewalls of the stacked structure 10, the exposed sidewalls of the second sacrificial layer 21, the exposed sidewalls and upper surface of the second semiconductor layer 22, and the upper surface of the field insulating layer 105. For example, the spacer material layer SM may be formed conformally. The spacer material layer SM may include at least one of, for example, silicon nitride (SiN), silicon oxycarbonitride (SiOCN), silicon boron carbonitride (SiBCN), silicon carbonitride (SiCN), silicon oxynitride (SiON), and/or combinations thereof.

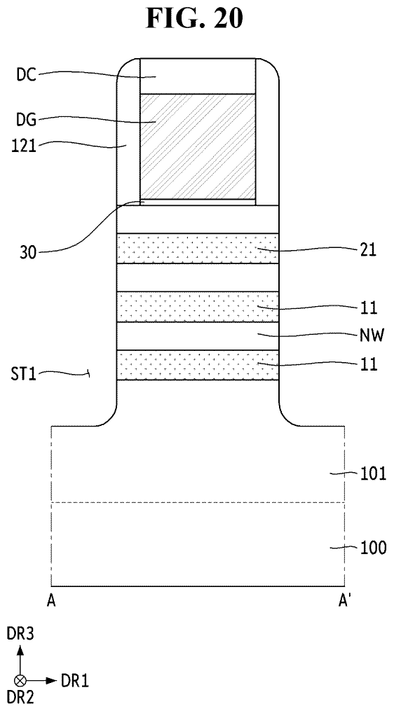

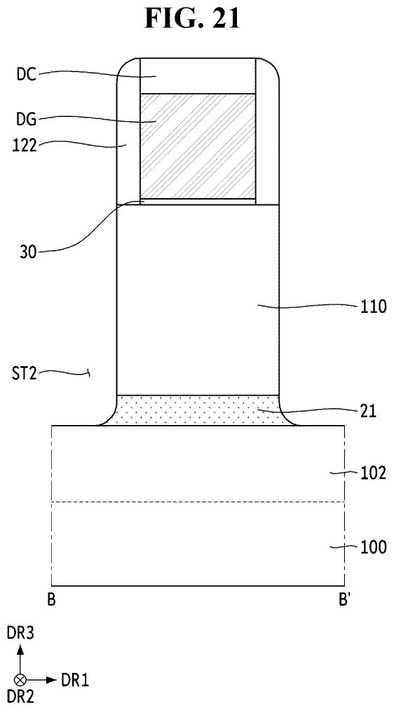

Referring to FIGS. 20 and 21, using the dummy gate DG and the dummy capping pattern DC as masks, the stacked structure 10 (see FIGS. 17 to 19), the second sacrificial layer 21, and the second semiconductor layer 22 (see FIGS. 17 to 19) may be etched to form the first and second source/drain trenches ST1, ST2, respectively. For example, the first source/drain trench ST1 may be formed on the first active pattern 101. The second source/drain trench ST2 may be formed on the second active pattern 102. While each of the first and second source/drain trenches ST1, ST2 is being formed, the spacer material layer SM (see FIGS. 17 to 19) formed on the upper surface of the dummy capping pattern DC and a portion of each of the dummy capping patterns DC may be etched.

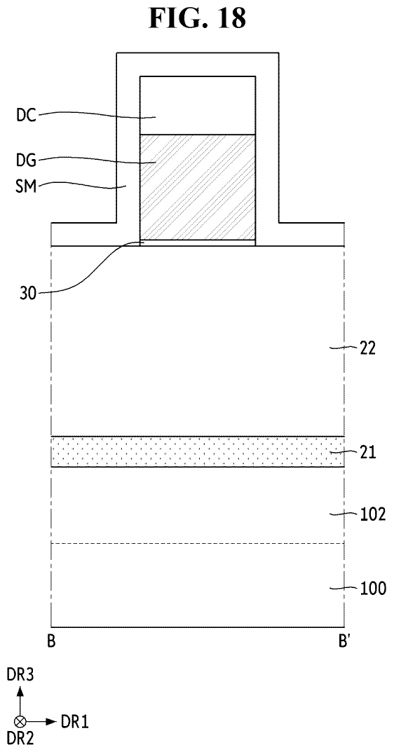

For example, after the first and second source/drain trenches ST1, ST2 are formed, respectively, the spacer material layer SM (see FIGS. 17 to 19) remaining on the sidewalls of each of the dummy capping pattern DC and the dummy gate DG may be defined as the first and second gate spacers 121, 122. For example, after the first source/drain trench ST1 is formed, each of the first semiconductor layer 12 (see FIG. 17) and the second semiconductor layer 22 (see FIG. 17) remaining beneath the dummy gate DG on the first active pattern 101 may be defined as a plurality of nanosheets NW. Additionally, after the second source/drain trench ST2 is formed, the second semiconductor layer 22 (see FIG. 18) remaining beneath the dummy gate DG on the second active pattern 102 may be defined as a fin-shaped pattern 110.

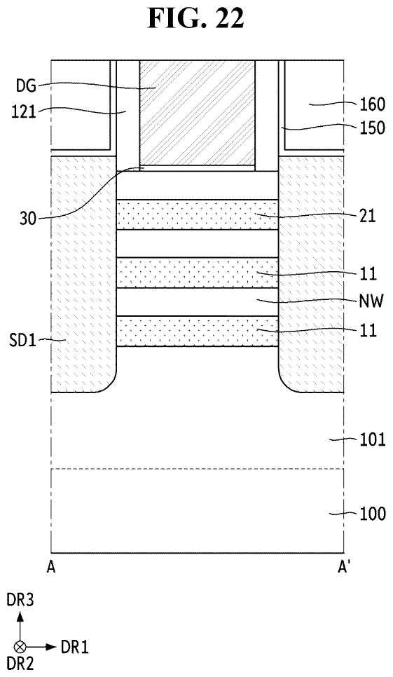

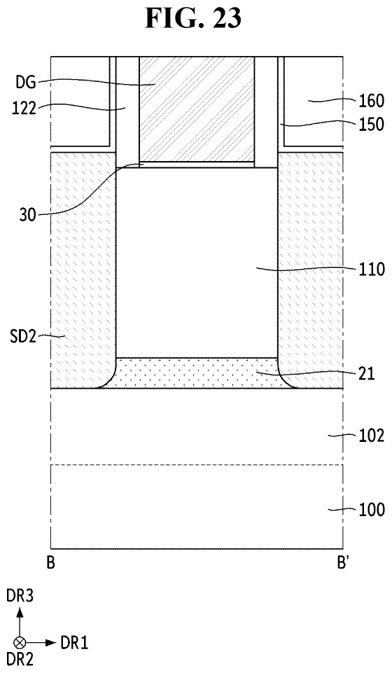

Referring to FIGS. 22 and 23, the first source/drain region SD1 may be formed inside the first source/drain trench ST1 (see FIG. 20). For example, the first source/drain region SD1 may be in contact with both sidewalls in the first horizontal direction DR1 of each of the plurality of nanosheets NW, the first sacrificial layer 11 and the second sacrificial layer 21. Additionally, the second source/drain region SD2 may be formed inside the second source/drain trench ST2 (see FIG. 21). For example, the second source/drain region SD2 may be in contact with both sidewalls in the first horizontal direction DR1 of each of the fin-shaped pattern 110 and the second sacrificial layer 21.

Subsequently, the first etching stop layer 150 may be formed on the surface of each of the first and second source/drain regions SD1, SD2, and on the sidewalls of each of the first and second gate spacers 121, 122. Although not shown, the first etching stop layer 150 may also be formed on the upper surface of the field insulating layer 105. For example, the first etching stop layer 150 may be formed conformally. Subsequently, the first interlayer insulating layer 160 may be formed on the first etching stop layer 150. Subsequently, through a planarization process, the upper surface of the dummy gate DG may be exposed.

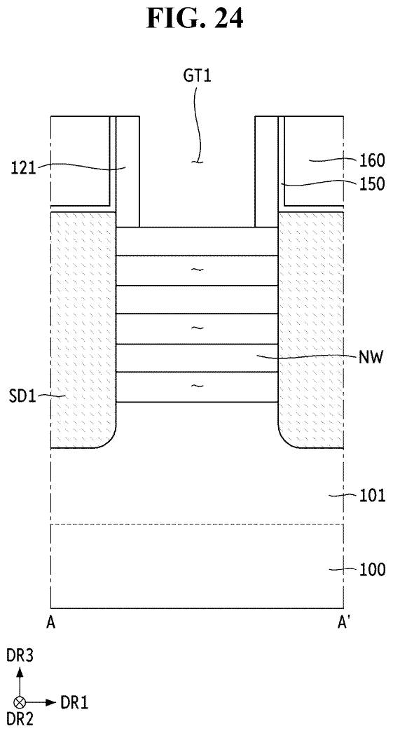

Referring to FIGS. 24 to 26, the dummy gate DG (see FIGS. 22 and 23), the pad oxide layer 30 (see FIGS. 22 and 23), the first sacrificial layer 11 (see FIGS. 22 and 23), and the second sacrificial layer 21 (see FIGS. 22 and 23) may each be etched. For example, the portions where the dummy gate DG (see FIGS. 22 and 23), the pad oxide layer 30 (see FIGS. 22 and 23), the first sacrificial layer 11 (see FIGS. 22 and 23), and the second sacrificial layer 21 (see FIGS. 22 and 23) are each etched may be defined as the first gate trench GT1.

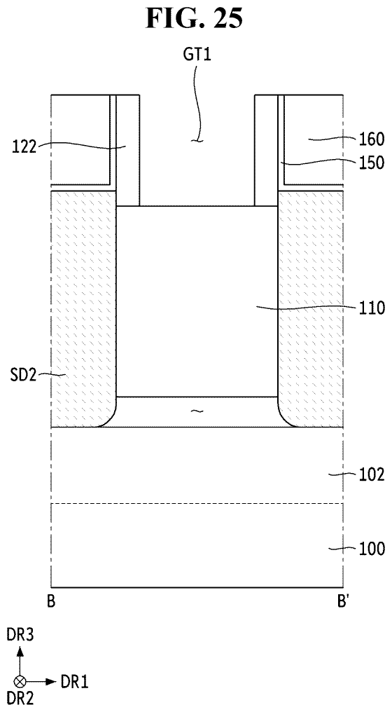

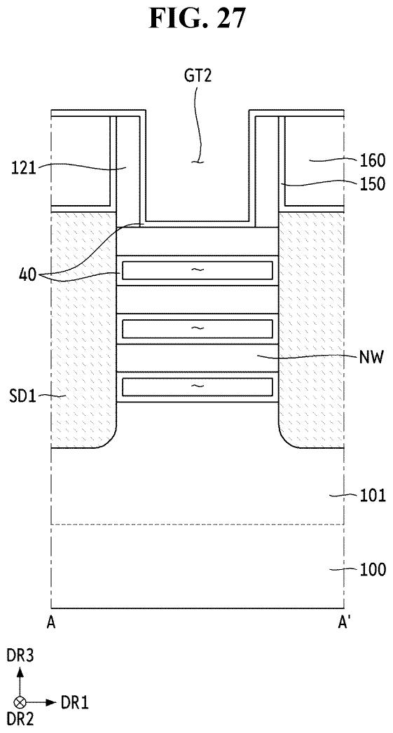

Referring now to FIGS. 27 to 29, a first liner layer 40 may be formed along the exposed surface inside the first gate trench GT1 (see FIGS. 24 and 25). For example, the first liner layer 40 may be formed conformally. For example, the first liner layer 40 may be formed on the upper surfaces of each of the first and second gate spacers 121, 122, the first etching stop layer 150, and the first interlayer insulating layer 160. For example, the first liner layer 40 may include at least one of silicon oxide, silicon oxynitride, silicon nitride, or a high-k dielectric material having a dielectric constant greater than that of silicon oxide.

Subsequently, a protective layer 50 may be formed on the first liner layer 40 in the second active pattern 102 and the region adjacent to the second active pattern 102. For example, the protective layer 50 may at least partially surround the fin-shaped pattern 110. For example, the protective layer 50 may include a SOH (Spin-On Hardmask). After the protective layer 50 is formed, the exposed region on the first liner layer 40 may be defined as the second gate trench GT2.

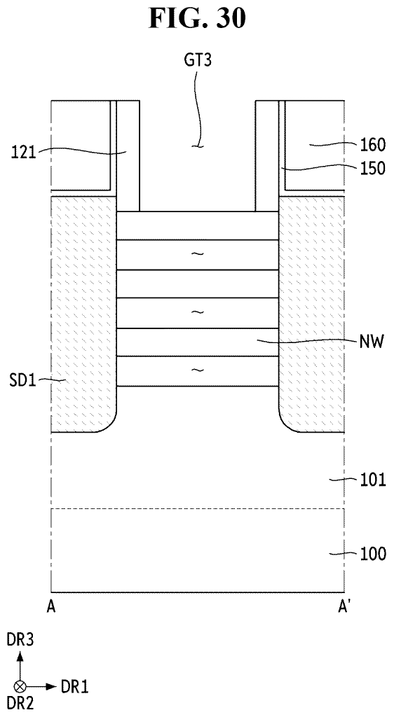

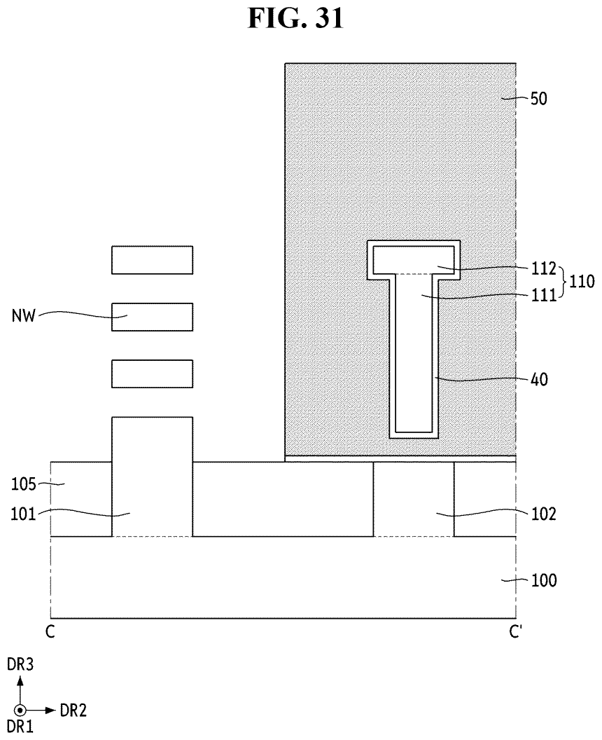

Referring to FIGS. 30 and 31, a portion of the first liner layer 40 exposed in the second gate trench GT2 (see FIG. 27) may be etched. For example, another portion of the first liner layer 40 in the portion where the protective layer 50 is formed may be left. For example, after a portion of the first liner layer 40 is etched, the exposed region may be defined as a third gate trench GT3.

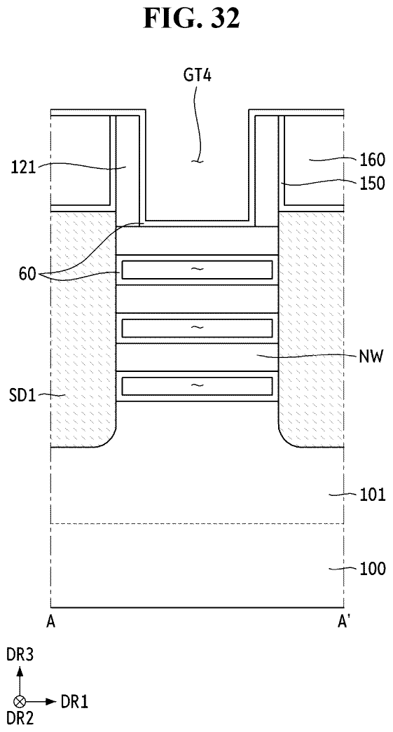

Referring to FIGS. 32 to 34, the protective layer 50 (see FIG. 31) may be removed. Accordingly, the first liner layer 40 (see FIG. 31) may be exposed. Subsequently, a second liner layer 60 may be formed on the exposed surface inside the third gate trench GT3 and on the first liner layer 40 (see FIG. 31). For example, the second liner layer 60 may be formed conformally. For example, the second liner layer 60 may be formed on the upper surfaces of each of the first and second gate spacers 121, 122, the first etching stop layer 150, and the first interlayer insulating layer 160. For example, the second liner layer 60 may include at least one of silicon oxide, silicon oxynitride, silicon nitride, or a high-k dielectric material having a dielectric constant greater than that of silicon oxide.

For example, after the second liner layer 60 is formed, the layer including the first liner layer 40 (see FIG. 31) and the second liner layer 60 formed on the first liner layer 40 (see FIG. 31) may be defined as a third liner layer 70. For example, the thickness of the third liner layer 70 may be greater than the thickness of the second liner layer 60. For example, after the second liner layer 60 and the third liner layer 70 are formed, the exposed regions on each of the second liner layer 60 and the third liner layer 70 may be defined as a fourth gate trench GT4.

In some other example embodiments, the first and second gate insulating layers 131, 132 may be formed through a fabrication process of forming the second gate insulating layer 132 on the surfaces of each of the plurality of nanosheets NW and the fin-shaped pattern 110, covering the second gate insulating layer 132 formed on the surface of the fin-shaped pattern 110 with a protective layer, and etching a portion of the second gate insulating layer 132 formed on the surfaces of the plurality of nanosheets NW to form the first gate insulating layer 131.

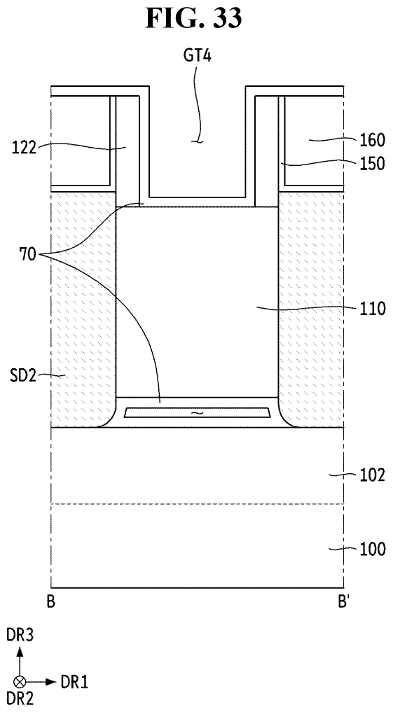

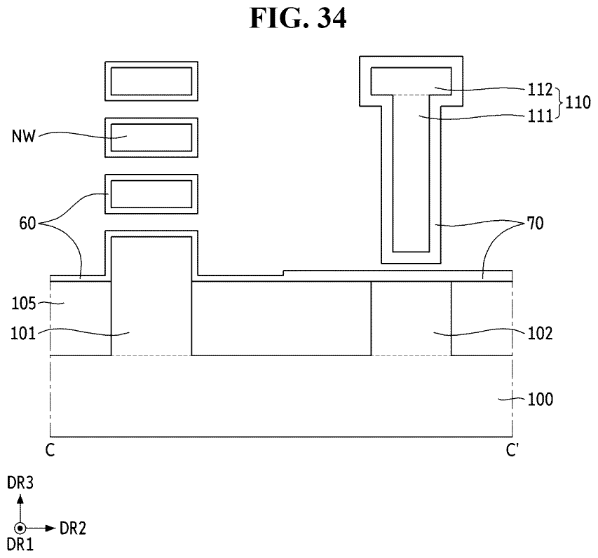

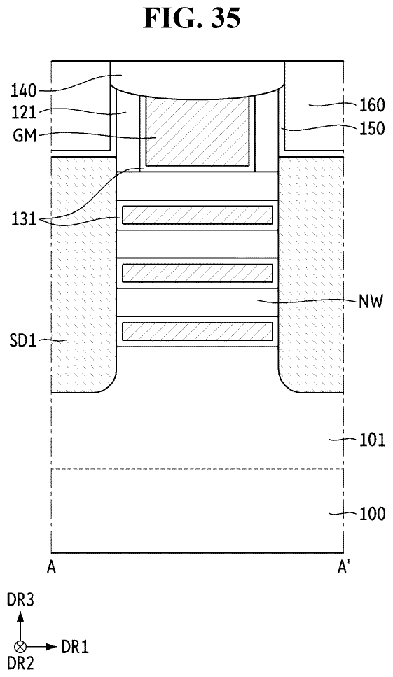

Referring to FIGS. 35 to 37, inside the fourth gate trench GT4 (see FIGS. 32 and 33), a gate material layer GM may be formed on each of the second liner layer 60 (see FIGS. 32 and 34) and the third liner layer 70 (see FIGS. 33 and 34). For example, the gate material layer GM may extend in the second horizontal direction DR2. For example, the gate material layer GM may at least partially surround each of the plurality of nanosheets NW and fin-shaped patterns 110. The gate material layer GM may include the same material as the gate electrode G1. After the gate material layer GM is formed, the second liner layer 60 (see FIGS. 32 and 34) may be defined as the first gate insulating layer 131, and the third liner layer 70 (see FIGS. 33 and 34) may be defined as the second gate insulating layer 132.

Subsequently, a capping material layer 140 may be formed on the upper surfaces of each of the first etching stop layer 150, the first and second gate spacers 121, 122, the first and second gate insulating layers 131, 132, and the gate material layer GM. For example, the capping material layer 140 may extend in the second horizontal direction DR2. The capping material layer 140 may include the same material as each of the first and second capping patterns 141, 142.

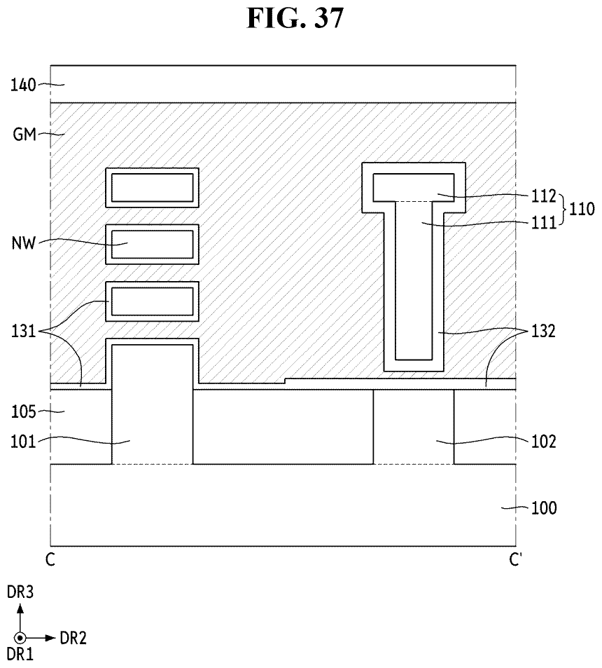

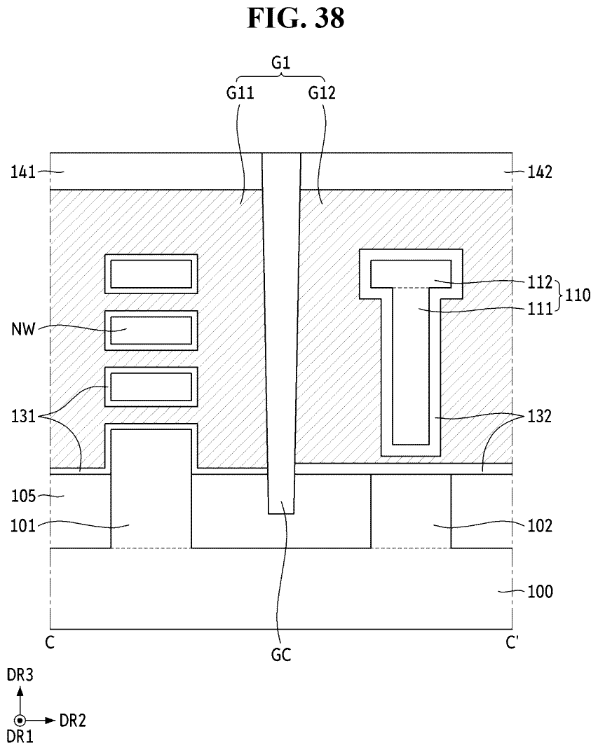

Referring to FIG. 38, the gate cut GC that penetrates each of the capping material layer 140 (see FIG. 37), the gate material layer GM (see FIG. 37), and the first and second gate insulating layers 131, 132 in the vertical direction DR3 and extends into the inside of the field insulating layer 105 may be formed. The gate cut GC may separate the capping material layer 140 (see FIG. 37) into first and second capping patterns 141, 142. Additionally, the gate cut GC may separate the gate material layer GM (see FIG. 37) into the first and second gate electrodes G11, G12.

Referring to FIGS. 2 to 4, the first and second gate contacts CB1, CB2, the first and second source/drain contacts CA1, CA2, the silicide layer SL, the second etching stop layer 170, the second interlayer insulating layer 180, and the first and second vias V1, V2 may each be formed. Through this fabrication process, the semiconductor device shown in FIGS. 2 to 4 may be fabricated.

The fabrication method of the semiconductor device according to some embodiments of the present disclosure may simplify the fabrication process by simultaneously forming a plurality of nanosheets NW of a transistor (MBCFET™ (Multi-Bridge Channel Field Effect Transistor)) including a plurality of nanosheets NW, and a fin-shaped pattern 110 of a fin-shaped transistor (FinFET). In the semiconductor device according to some embodiments of the present disclosure fabricated by the above-mentioned fabrication method, the fin-shaped pattern 110 may be spaced apart from the plurality of nanosheets NW in the second horizontal direction DR2 and may be spaced apart from the upper surface of the second active pattern 102 in the vertical direction DR3. Additionally, in the semiconductor device according to some example embodiments of the present disclosure, the fin-shaped pattern 110 may include a first portion 111 spaced apart from the upper surface of the second active pattern 102 in the vertical direction DR3 and a second portion 112 being in contact with the upper surface of the first portion 111, and the width W2 of the second portion 112 of the fin-shaped pattern 110 in the second horizontal direction DR2 may be larger than the width W1 of the first portion 111 of the fin-shaped pattern 110 in the second horizontal direction DR2.

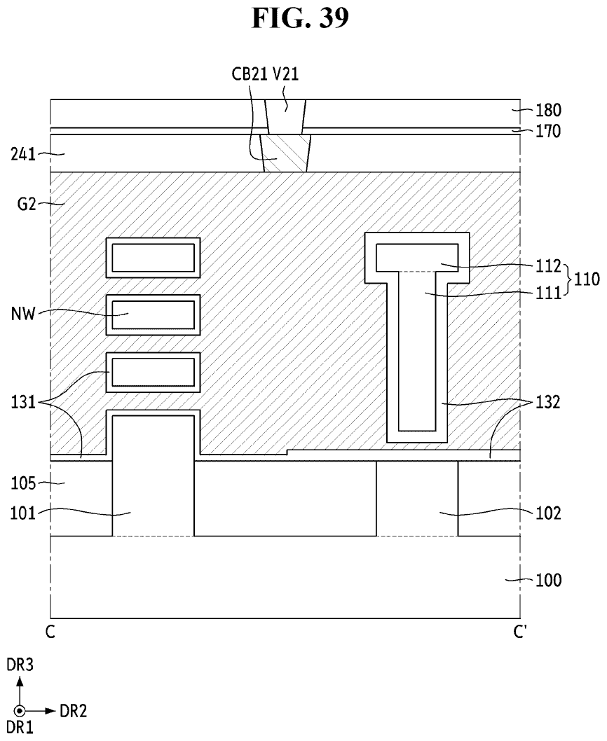

Hereinafter, a semiconductor device according to several other example embodiments of the present disclosure will be described with reference to FIG. 39. The explanation will focus on the differences from the semiconductor device shown in FIGS. 1 to 4.

FIG. 39 is a cross-sectional view for explaining a semiconductor device according to some other example embodiments of the present disclosure.

Referring to FIG. 39, in the semiconductor device according to some other example embodiments of the present disclosure, a plurality of nanosheets NW and a fin-shaped pattern 110 may be at least partially surrounded by a single gate electrode G2.

For example, the capping pattern 241 may extend in the second horizontal direction DR2 on the gate electrode G2. The gate contact CB21 may penetrate the capping pattern 241 in the vertical direction DR3 to be connected to the gate electrode G2. The via V21 may penetrate the second interlayer insulating layer 180 and the second etching stop layer 170 in the vertical direction DR3 to be connected to the gate contact CB21. For example, the first gate insulating layer 131 and the second gate insulating layer 132 may have a step difference on the upper surface of the field insulating layer 105.

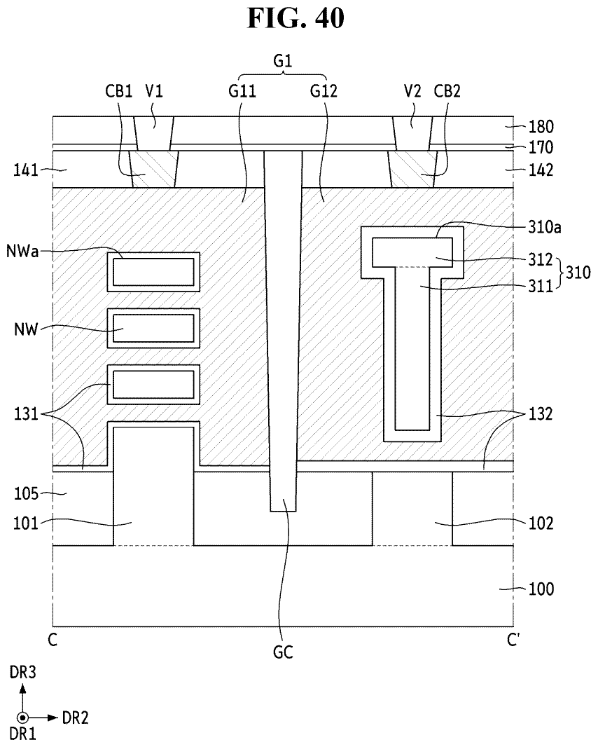

Hereinafter, a semiconductor device according to other example embodiments of the present disclosure will be described with reference to FIG. 40. The description will focus on the differences from the semiconductor device shown in FIGS. 1 to 4.

FIG. 40 is a cross-sectional view for explaining a semiconductor device according to another several example embodiments of the present disclosure.

Referring to FIG. 40, in the semiconductor device according to some other example embodiments of the present disclosure, the upper surface 310a of the fin-shaped pattern 310 may be formed higher than the upper surface NWa of the uppermost nanosheet of the plurality of nanosheets NW.

For example, the fin-shaped pattern 310 may include a first portion 311 spaced apart from the upper surface of the second active pattern 102 in the vertical direction DR3 and a second portion 312 being in contact with the upper surface of the first portion 311. For example, the upper surface 310a of the second portion 312 of the fin-shaped pattern 310 may be formed higher than the upper surface NWa of the uppermost nanosheet of the plurality of nanosheets NW.

Hereinafter, the fabrication method of the semiconductor device shown in FIG. 40 will be described with reference to FIG. 40 to FIG. 45. The description will focus on the differences from the fabrication method of the semiconductor device shown in FIGS. 5 to 38.

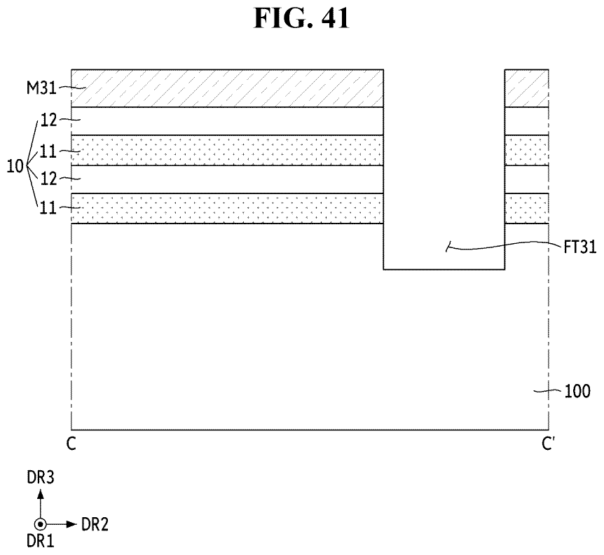

FIGS. 41 to 45 are intermediate stage diagrams for explaining the fabrication method of a semiconductor device shown in FIG. 40.

Referring to FIG. 41, the stacked structure 10 may be formed on the substrate 100. The stacked structure 10 may include the first sacrificial layer 11 and the first semiconductor layer 12 alternately stacked on the substrate 100. For example, the first sacrificial layer 11 may be formed at the lowermost portion of the stacked structure 10, and the first semiconductor layer 12 may be formed at the uppermost portion of the stacked structure 10. For example, the first sacrificial layer 11 may include silicon germanium (SiGe). For example, the first semiconductor layer 12 may include silicon (Si).

Subsequently, the first mask pattern M31 may be formed on the upper surface of the stacked structure 10. Then, using the first mask pattern M31 as a mask, the stacked structure 10 may be etched to form a fin trench FT31 inside the stacked structure 10. For example, the fin trench FT31 may extend into the inside of the substrate 100. That is, the bottom surface of the fin trench FT31 may be formed lower than the bottom surface of the stacked structure 10.

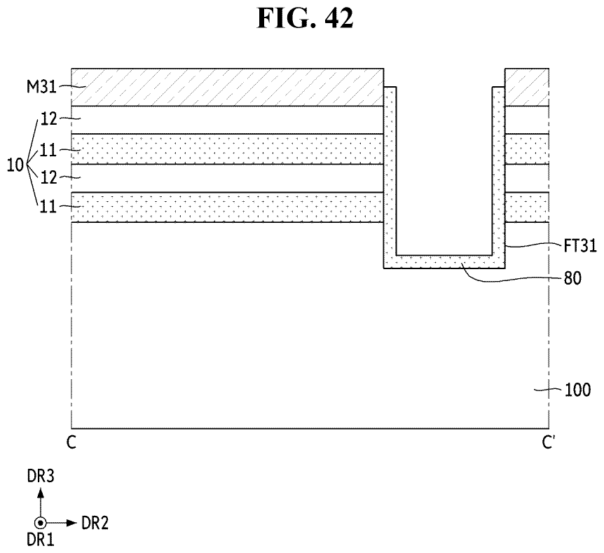

Referring to FIG. 42, a third sacrificial layer 80 may be formed on the bottom surface and sidewalls of the fin trench FT31. For example, the third sacrificial layer 80 may also be formed on a portion of the sidewalls of the first mask pattern M31. For example, the uppermost surface of the third sacrificial layer 80 may be formed between the bottom surface of the first mask pattern M31 and an upper surface of the first mask pattern M31. For example, the uppermost surface of the third sacrificial layer 80 may be formed higher than the upper surface of the stacked structure 10. For example, the third sacrificial layer 80 may be formed conformally. For example, the third sacrificial layer 80 may include the same material as the first sacrificial layer 11. That is, the third sacrificial layer 80 may include silicon germanium (SiGe).

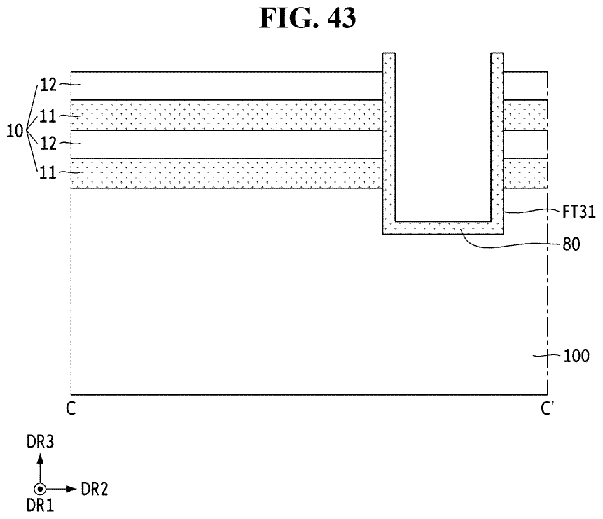

Referring to FIG. 43, the first mask pattern M31 (see FIG. 42) may be removed. Accordingly, the upper surface of the stacked structure 10 may be exposed.

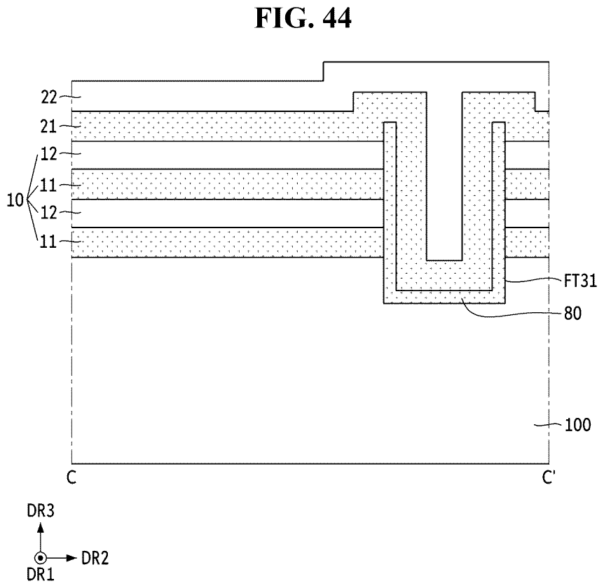

Referring to FIG. 44, the second sacrificial layer 21 and the second semiconductor layer 22 may be formed sequentially along the upper surface of the stacked structure 10, the sidewalls and the upper surface of the third sacrificial layer 80. For example, each of the second sacrificial layer 21 and the second semiconductor layer 22 may be conformally formed. For example, the fin trench FT31 may be completely filled by the second sacrificial layer 21 and the second semiconductor layer 22. For example, the upper surface of the second sacrificial layer 21 formed on the fin trench FT31 may be formed higher than the upper surface of the second sacrificial layer 21 formed on the stacked structure 10. Further, the upper surface of the second semiconductor layer 22 formed on the fin trench FT31 may be formed higher than the upper surface of the second semiconductor layer 22 formed on the stacked structure 10. For example, the second sacrificial layer 21 may include silicon germanium (SiGe), and the second semiconductor layer 22 may include silicon (Si).

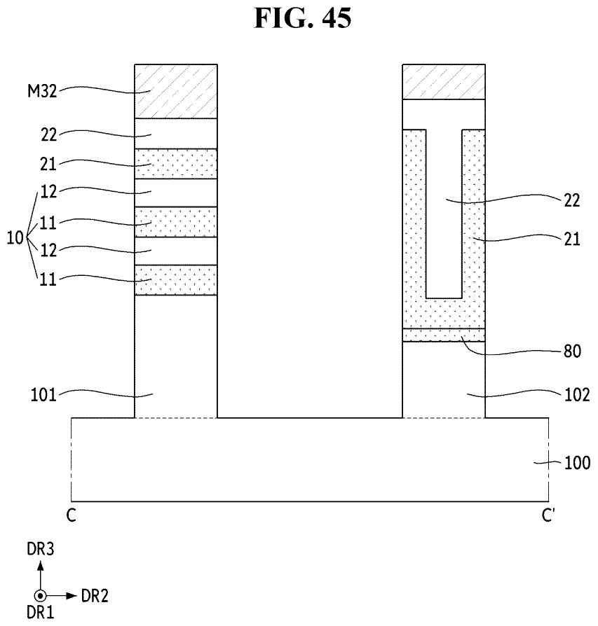

Referring to FIG. 45, a second mask pattern M32 may be formed on the second semiconductor layer 22. Subsequently, using the second mask pattern M32 as a mask, each of the stacked structure 10, the second sacrificial layer 21, the second semiconductor layer 22, and the third sacrificial layer 80 may be etched. While the stacked structure 10, the second sacrificial layer 21, the second semiconductor layer 22, and the third sacrificial layer 80 are each being etched, a portion of the substrate 100 may also be etched. Through this etching process, the first active pattern 101 may be defined beneath the stacked structure 10 on the upper surface of the substrate 100, and the second active pattern 102 may be defined beneath the third sacrificial layer 80.

Referring to FIG. 40, after performing the fabrication process shown in FIGS. 16 to 38, the first and second gate contacts CB1, CB2, the second etching stop layer 170, the second interlayer insulating layer 180, and the first and second vias V1, V2 may each be formed. Through this fabrication process, the semiconductor device shown in FIG. 40 may be fabricated.

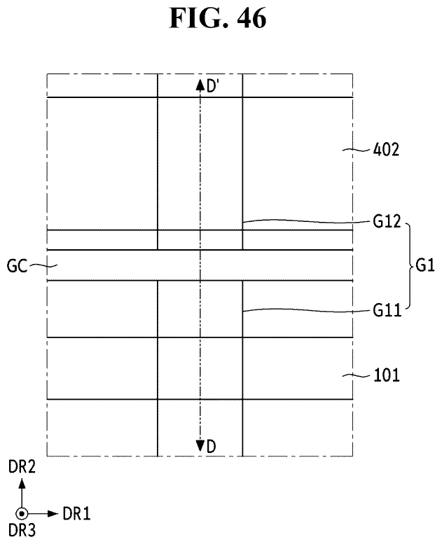

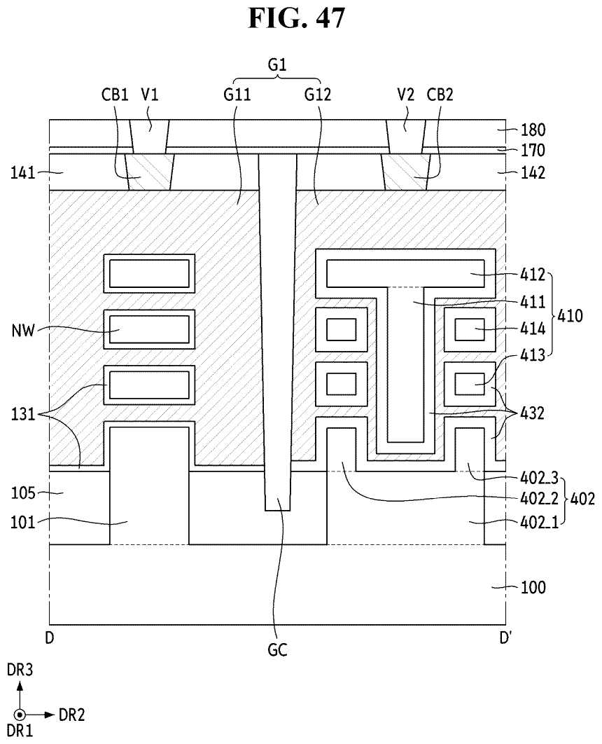

Hereinafter, a semiconductor device according to several other example embodiments of the present disclosure will be described with reference to FIGS. 46 and 47. The description will focus on the differences from the semiconductor device shown in FIGS. 1 to 4.

FIG. 46 is a layout diagram for explaining a semiconductor device according to another several example embodiments of the present disclosure. FIG. 47 is a cross-sectional view taken along the line D-D′ of FIG. 46.

Referring to FIGS. 46 and 47, in the semiconductor device according to another several example embodiments of the present disclosure, the fin-shaped pattern 410 may include first to fourth portions 411, 412, 413, 414.

For example, the width of the second active pattern 402 in the second horizontal direction DR2 may be greater than the width of the first active pattern 101 in the second horizontal direction DR2. For example, the second active pattern 402 may include a first portion 402_1, a second portion 402_2, and a third portion 402_3. The first portion 402_1 of the second active pattern 402 may be disposed inside or between portions of the field insulating layer 105. The width in the second horizontal direction DR2 of the first portion 402_1 of the second active pattern 402 may be greater than the width of the second horizontal direction DR2 of the first active pattern 101. Each of the second portion 402_2 of the second active pattern 402 and the third portion 402_3 of the second active pattern 402 may protrude in the vertical direction DR3 from the upper surface of the first portion 402_1 of the second active pattern 402. The third portion 402_3 of the second active pattern 402 may be spaced apart from the second portion 402_2 of the second active pattern 402 in the second horizontal direction DR2. For example, the upper surfaces of each of the second portion 402_2 of the second active pattern 402 and the third portion 402_3 of the second active pattern 402 may be formed on the same plane as the upper surface of the first active pattern 101.

For example, the first portion 411 of the fin-shaped pattern 410 may be spaced apart from the upper surface of the first portion 402_1 of the second active pattern 402 in the vertical direction DR3. For example, the first portion 411 of the fin-shaped pattern 410 may be disposed between the second portion 402_2 of the second active pattern 402 and the third portion 402_3 of the second active pattern 402. The second portion 412 of the fin-shaped pattern 410 may be in contact with the upper surface of the first portion 411 of the fin-shaped pattern 410. For example, the first portion 411 and the second portion 412 of the fin-shaped pattern 410 may be integrally formed. For example, the width of the second portion 412 of the fin-shaped pattern 410 in the second horizontal direction DR2 may be greater than the width of the plurality of nanosheets NW in the second horizontal direction DR2.

For example, the third portion 413 of the fin-shaped pattern 410 may be disposed on both sidewalls of the first portion 411 of the fin-shaped pattern 410 in the second horizontal direction DR2. The third portion 413 of the fin-shaped pattern 410 may be spaced apart from both sidewalls in the second horizontal direction DR2 of the first portion 411 of the fin-shaped pattern 410 in the second horizontal direction DR2. The third portion 413 of the fin-shaped pattern 410 may be disposed between the upper surface of the second portion 402_2 of the second active pattern 402 and the bottom surface of the second portion 412 of the fin-shaped pattern 410. Further, the third portion 413 of the fin-shaped pattern 410 may be disposed between the upper surface of the third portion 402_3 of the second active pattern 402 and the bottom surface of the second portion 412 of the fin-shaped pattern 410. The third portion 413 of the fin-shaped pattern 410 may be spaced apart in the vertical direction DR3 from each of the second portion 402_2 of the second active pattern 402 and the third portion 402_3 of the second active pattern 402.

For example, the fourth portion 414 of the fin-shaped pattern 410 may be disposed on both sidewalls of the first portion 411 of the fin-shaped pattern 410 in the second horizontal direction DR2. The fourth portion 414 of the fin-shaped pattern 410 may be spaced apart from both sidewalls in the second horizontal direction DR2 of the first portion 411 of the fin-shaped pattern 410 in the second horizontal direction DR2. The fourth portion 414 of the fin-shaped pattern 410 may be disposed between the upper surface of the third portion 413 of the fin-shaped pattern 410 and the bottom surface of the second portion 412 of the fin-shaped pattern 410. The fourth portion 414 of the fin-shaped pattern 410 may be spaced apart from the third portion 413 of the fin-shaped pattern 410 in the vertical direction DR3. Further, the second portion 412 of the fin-shaped pattern 410 may be spaced apart from the fourth portion 414 of the fin-shaped pattern 410 in the vertical direction DR3. For example, the third portion 413 of the fin-shaped pattern 410 and the fourth portion 414 of the fin-shaped pattern 410 may each overlap in the vertical direction DR3 with each of the second portion 402_2 of the second active pattern 402 and the third portion 402_3 of the second active pattern 402.

For example, the second gate insulating layer 432 may be disposed between the second gate electrode G12 and each of the first to third portions 402_1, 402_2, and 402_3 of the second active pattern 402. The second gate insulating layer 432 may be disposed between the second gate electrode G12 and each of the first to fourth portions 411, 412, 413, 414 of the fin-shaped pattern 410.

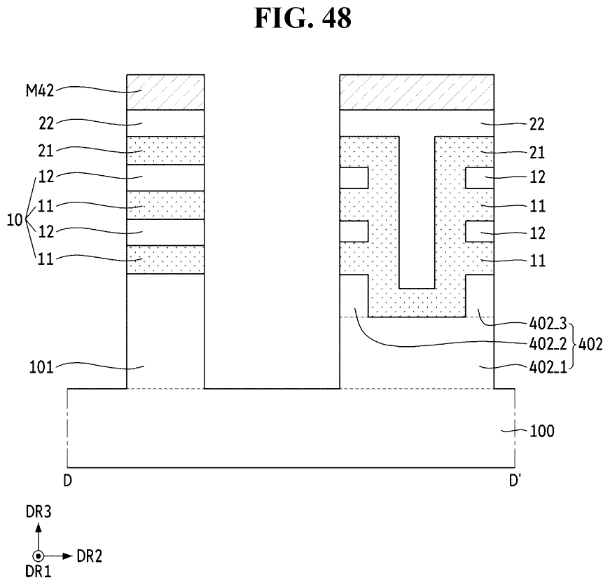

Hereinafter, the fabrication method of the semiconductor device shown in FIGS. 46 and 47 will be explained with reference to FIGS. 47 and 48. The explanation will focus on the differences from the fabrication method of the semiconductor device shown in FIGS. 5 to 38.

FIG. 48 is an intermediate stage diagram for explaining the fabrication method of the semiconductor device shown in FIGS. 46 and 47.

Referring to FIG. 48, after performing the fabrication process shown in FIGS. 5 to 12, the second mask pattern M42 may be formed on the second semiconductor layer 22. For example, the width in the second horizontal direction DR2 of the second mask pattern M42 disposed on the upper surface of the second active pattern 402, which will be described later, may be greater than the width in the second horizontal direction DR2 of the second mask pattern M42 disposed on the upper surface of the first active pattern 101, which will be described later. Subsequently, using the second mask pattern M42 as a mask, the stacked structure 10, the second sacrificial layer 21, and the second semiconductor layer 22 may each be etched. While the stacked structure 10, the second sacrificial layer 21, and the second semiconductor layer 22 are each being etched, a portion of the substrate 100 may also be etched. Through this etching process, the first active pattern 101 may be defined beneath the stacked structure 10 on the upper surface of the substrate 100, and the second active pattern 402 may be defined beneath the second sacrificial layer 21 and the second semiconductor layer 22.

For example, the second active pattern 402 may include a first portion 402_1, a second portion 402_2, and a third portion 402_3. Each of the second portion 402_2 and the third portion 402_3 of the second active pattern 402 may protrude in the vertical direction DR3 from the upper surface of the first portion 402_1 of the second active pattern 402. The third portion 402_3 of the second active pattern 402 may be spaced apart from the second portion 402_2 of the second active pattern 402 in the second horizontal direction DR2. For example, each of the first sacrificial layer 11 and the first semiconductor layer 12 may be left on each of the second portion 402_2 and the third portion 402_3 of the second active pattern 402.

Referring to FIG. 47, after performing the fabrication process shown in FIGS. 16 to 38, the first and second gate contacts CB1, CB2, the second etching stop layer 170, the second interlayer insulating layer 180, and the first and second vias V1, V2 may each be formed. Through this fabrication process, the semiconductor device shown in FIG. 47 may be fabricated.

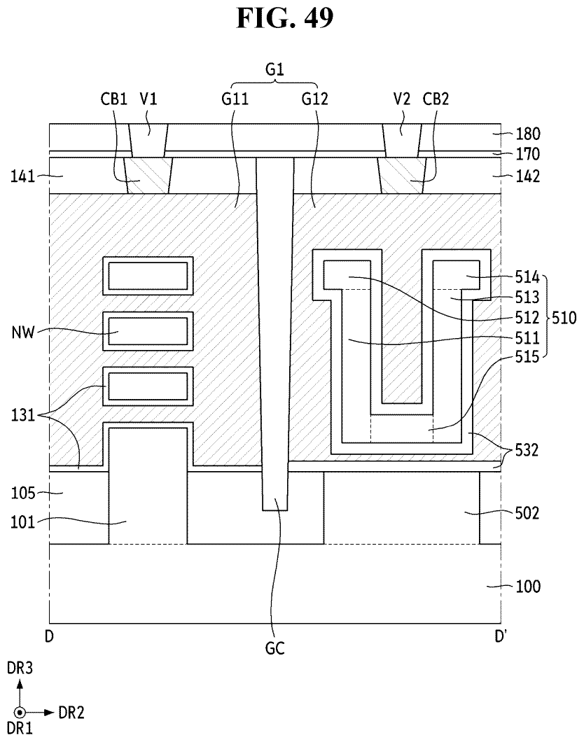

Hereinafter, a semiconductor device according to some other exemplary embodiments of the present disclosure will be described with reference to FIG. 49. The description will focus on the differences from the semiconductor device shown in FIGS. 1 to 4.

FIG. 49 is a cross-sectional view for explaining a semiconductor device according to several other example embodiments of the present disclosure.

Referring to FIG. 49, a semiconductor device according to several other example embodiments of the present disclosure may have a fin-shaped pattern 510 that is U-shaped configuration.

For example, the width of the second active pattern 502 in the second horizontal direction DR2 may be greater than the width of the first active pattern 101 in the second horizontal direction DR2. For example, the fin-shaped pattern 510 may include first, second, third, fourth, and fifth portions 511, 512, 513, 514, 515. For example, the first portion 511 of the fin-shaped pattern 510 may be spaced apart from the upper surface of the second active pattern 502 in the vertical direction DR3. The second portion 512 of the fin-shaped pattern 510 may be in contact with the upper surface of the first portion 511 of the fin-shaped pattern 510. The third portion 513 of the fin-shaped pattern 510 may be spaced apart from the upper surface of the second active pattern 502 in the vertical direction DR3. The third portion 513 of the fin-shaped pattern 510 may be spaced apart from the first portion 511 of the fin-shaped pattern 510 in the second horizontal direction DR2. The fourth portion 514 of the fin-shaped pattern 510 may be in contact with the upper surface of the third portion 513 of the fin-shaped pattern 510. The fourth portion 514 of the fin-shaped pattern 510 may be spaced apart from the second portion 512 of the fin-shaped pattern 510 in the second horizontal direction DR2.

The fifth portion 515 of the fin-shaped pattern 510 may be spaced apart from the upper surface of the second active pattern 502 in the vertical direction DR3. The fifth portion 515 of the fin-shaped pattern 510 may connect the lower sidewall of the first portion 511 of the fin-shaped pattern 510 to the lower sidewall of the third portion 513 of the fin-shaped pattern 510. For example, the bottom surfaces of each of the first portion 511 of the fin-shaped pattern 510, the third portion 513 of the fin-shaped pattern 510, and the fifth portion 515 of the fin-shaped pattern 510 may be formed on the same plane. For example, the second gate insulating layer 532 may be disposed between the second gate electrode G12 and the second active pattern 502. The second gate insulating layer 532 may be disposed between the second gate electrode G12 and each of the first, second, third, fourth, and fifth portions 511, 512, 513, 514, 515 of the fin-shaped pattern 510.

Hereinafter, a fabrication method of the semiconductor device shown in FIG. 49 will be described with reference to FIG. 49 to FIG. 52. The description will focus on the differences from the fabrication method of the semiconductor device shown in FIGS. 5 to 38.

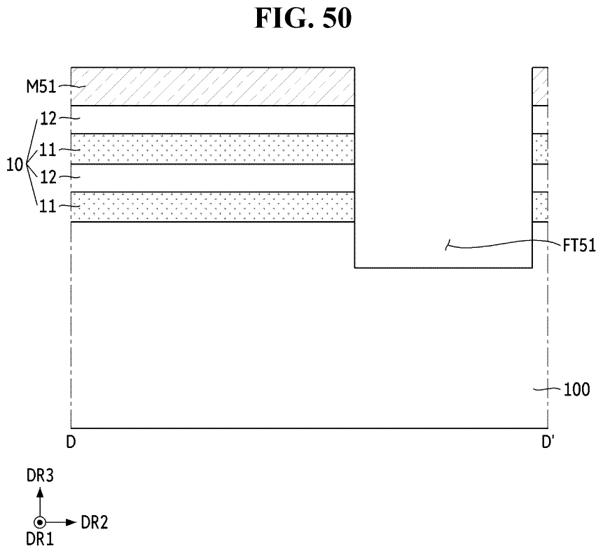

FIGS. 50 to 52 are intermediate stage diagrams for explaining the fabrication method of the semiconductor device shown in FIG. 49.

Referring to FIG. 50, the stacked structure 10 may be formed on the substrate 100. The stacked structure 10 may include the first sacrificial layer 11 and the first semiconductor layer 12 alternately stacked on the substrate 100. For example, the first sacrificial layer 11 may be formed at the lowermost portion of the stacked structure 10 and the first semiconductor layer 12 may be formed at the uppermost portion of the stacked structure 10. For example, the first sacrificial layer 11 may include silicon germanium (SiGe). For example, the first semiconductor layer 12 may include silicon (Si).

Subsequently, the first mask pattern M51 may be formed on the upper surface of the stacked structure 10. Then, using the first mask pattern M51 as a mask, the stacked structure 10 may be etched to form the fin trench FT51 inside the stacked structure 10. For example, the fin trench FT51 may extend into the inside of the substrate 100. That is, the bottom surface of the fin trench FT51 may be formed lower than the bottom surface of the stacked structure 10.

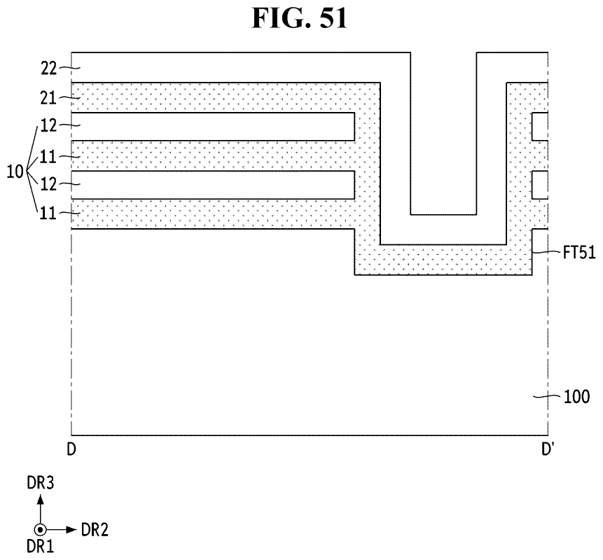

Referring to FIG. 51, the first mask pattern M51 (see FIG. 50) may be removed. Subsequently, the second sacrificial layer 21 and the second semiconductor layer 22 may be formed sequentially on the upper surface of the stacked structure 10, the bottom surface and the sidewalls of the fin trench FT51. For example, each of the second sacrificial layer 21 and the second semiconductor layer 22 may be conformally formed. For example, a void may be formed on the second semiconductor layer 22 inside the fin trench FT51. For example, the second sacrificial layer 21 may include silicon germanium (SiGe) and the second semiconductor layer 22 may include silicon (Si).

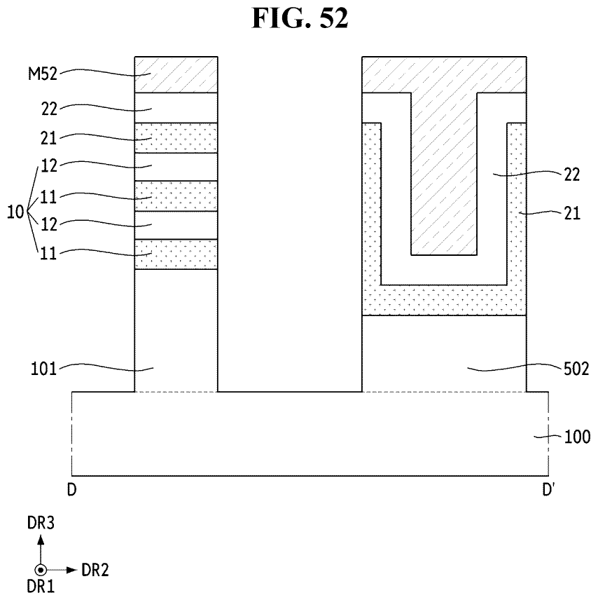

Referring to FIG. 52, the second mask pattern M52 may be formed on the second semiconductor layer 22. For example, the second mask pattern M52 may fill the void formed on the second semiconductor layer 22 inside the fin trench FT51 (see FIG. 51). For example, the width in the second horizontal direction DR2 of the second mask pattern M52 disposed on the upper surface of the second active pattern 502, which will be described later, may be greater than the width in the second horizontal direction DR2 of the second mask pattern M52 disposed on the upper surface of the first active pattern 101, which will be described later. Subsequently, using the second mask pattern M52 as a mask, the stacked structure 10, the second sacrificial layer 21, and the second semiconductor layer 22 may each be etched. While the stacked structure 10, the second sacrificial layer 21, and the second semiconductor layer 22 is each being etched, a portion of the substrate 100 may also be etched. Through this etching process, the first active pattern 101 may be defined beneath the stacked structure 10 on the upper surface of the substrate 100, and the second active pattern 502 may be defined beneath the second sacrificial layer 21 and the second semiconductor layer 22.

Referring to FIG. 49, after performing the fabrication process shown in FIGS. 16 to 38, the first and second gate contacts CB1, CB2, the second etching stop layer 170, the second interlayer insulating layer 180, and the first and second vias V1, V2 may each be formed. Through this fabrication process, the semiconductor device shown in FIG. 49 may be fabricated.

While example embodiments according to the present disclosure have been described above with reference to the accompanying drawings, it will be understood that the present disclosure is not limited to the above embodiments and may be fabricated in a variety of different forms, and those of ordinary skill in the art to which the present disclosure belongs, may recognize that it may be implemented in other specific forms without changing the technical idea or essential features of the present disclosure. Therefore, it should be understood that the above-described embodiments are examples in all respects and not restrictive.

What is claimed is:

1. A semiconductor device comprising:
a substrate;
a first active pattern extending in a first direction on the substrate;
a second active pattern extending in the first direction on the substrate, the second active pattern spaced apart from the first active pattern in a second direction intersecting the first direction;
a plurality of nanosheets spaced apart from each other in a third direction perpendicular to the first direction and the second direction on the first active pattern;
a fin-shaped pattern spaced apart from the plurality of nanosheets in the second direction, the fin-shaped pattern comprising a first portion spaced apart from the second active pattern in the third direction and a second portion in contact with an upper surface of the first portion, wherein a width in the second direction of a bottom surface of the second portion is greater than a width in the second direction of the upper surface of the first portion; and
a gate electrode extending in the second direction on the first and second active patterns, the gate electrode at least partially surrounding each of the plurality of nanosheets and the fin-shaped pattern.

2. The semiconductor device of claim 1, further comprising:
a first gate insulating layer between the gate electrode and the plurality of nanosheets; and
a second gate insulating layer between the gate electrode and the fin-shaped pattern,
wherein a thickness of the second gate insulating layer is greater than a thickness of the first gate insulating layer.

3. The semiconductor device of claim 1, wherein at least a portion of the gate electrode is between an upper surface of the second active pattern and a bottom surface of the fin-shaped pattern.

4. The semiconductor device of claim 1, wherein a thickness of the second portion of the fin-shaped pattern is the same as a thickness of an uppermost nanosheet of the plurality of nanosheets in the third direction.

5. The semiconductor device of claim 1, wherein a width in the second direction of the first portion of the fin-shaped pattern is smaller than a width in the second direction of the plurality of nanosheets.

6. The semiconductor device of claim 1, further comprising:
a first source/drain region on a sidewall in the first direction of the plurality of nanosheets on the first active pattern; and
a second source/drain region on a sidewall in the first direction of the fin-shaped pattern on the second active pattern,
wherein an upper surface of the second source/drain region is the same distance from the substrate in the third direction as an upper surface of the first source/drain region.

7. The semiconductor device of claim 1, further comprising:
a gate cut penetrating the gate electrode in the direction, the gate cut separating the gate electrode into a first gate electrode and a second gate electrode,
wherein the first gate electrode at least partially surrounds the plurality of nanosheets, and the second gate electrode at least partially surrounds the fin-shaped pattern.

8. The semiconductor device of claim 7, wherein an upper surface of the second gate electrode is the same distance from the substrate in the third direction as an upper surface of the first gate electrode.

9. The semiconductor device of claim 1, wherein an upper surface of the fin-shaped pattern is the same distance from the substrate in the third direction as an upper surface of an uppermost nanosheet of the plurality of nanosheets.

10. The semiconductor device of claim 1, wherein a width in the second direction of the second active pattern is the same as a width in the second direction of the first active pattern.

11. The semiconductor device of claim 1, wherein the fin-shaped pattern further comprises:
a third portion spaced apart from sidewalls of the first portion in the second direction, between an upper surface of the second active pattern and the bottom surface of the second portion; and
a fourth portion spaced apart from sidewalls of the first portion in the second direction, between an upper surface of the third portion and the bottom surface of the second portion, and
wherein the third portion, the fourth portion, and the second portion are spaced apart in the third direction.

12. The semiconductor device of claim 1, wherein the fin-shaped pattern further comprises:
a third portion spaced apart from the first portion in the second direction;
a fourth portion spaced apart from the second portion in the second direction, the fourth portion being in contact with an upper surface of the third portion; and
a fifth portion in contact with lower sidewalls of the first portion and lower sidewalls of the third portion, and
wherein the bottom surfaces of each of the first portion, the third portion, and the fifth portion are the same distance from the substrate in the third direction.

13. A semiconductor device further comprising:
a substrate;
a first active pattern extending in a first direction on the substrate;
a second active pattern extending in the first direction on the substrate, the second active pattern spaced apart from the first active pattern in a second direction intersecting the first direction;
a plurality of nanosheets spaced apart from each other in a third direction perpendicular to the first direction and the second direction on the first active pattern;
a fin-shaped pattern spaced apart from the second active pattern in the third direction, the fin-shaped pattern spaced apart from the plurality of nanosheets in the second direction;
a gate electrode extending in the second direction on the first and second active patterns, the gate electrode at least partially surrounding each of the plurality of nanosheets and the fin-shaped pattern, at least a portion of the gate electrode between an upper surface of the second active pattern and a bottom surface of the fin-shaped pattern;
a first gate insulating layer between the gate electrode and the plurality of nanosheets; and
a second gate insulating layer between the gate electrode and the fin-shaped pattern,
wherein a thickness of the second gate insulating layer is greater than a thickness of the first gate insulating layer.

14. The semiconductor device of claim 13, wherein the fin-shaped pattern comprises:
a first portion spaced apart from the second active pattern in the third direction; and
a second portion in contact with an upper surface of the first portion, and
wherein a width in the second direction of a bottom surface of the second portion is greater than a width in the second direction of the upper surface of the first portion.

15. The semiconductor device of claim 14, wherein at least a portion of the bottom surface of the second portion of the fin-shaped pattern is in contact with the second gate insulating layer.

16. The semiconductor device of claim 14, wherein a width in the second direction of the second portion of the fin-shaped pattern is the same as a width in the second direction of an uppermost nanosheet of the plurality of nanosheets.

17. The semiconductor device of claim 13, wherein the upper surface of the second active pattern is lower than an upper surface of the first active pattern in the third direction.

18. The semiconductor device of claim 13, wherein an upper surface of the fin-shaped pattern is higher than an upper surface of an uppermost nanosheet of the plurality of nanosheets in the third direction.

19. The semiconductor device of claim 13, wherein a width in the second direction of the second active pattern is greater than a width in the second direction of the first active pattern.

20. A semiconductor device comprising:
a substrate;
a first active pattern extending in a first direction on the substrate;
a second active pattern extending in the first direction on the substrate, the second active pattern spaced apart from the first active pattern in a second direction intersecting the first direction, wherein an upper surface of the second active pattern is lower than an upper surface of the first active pattern in a third direction perpendicular to the first direction and the second direction, wherein a width in the second direction of the second active pattern is the same as a width in the second direction of the first active pattern;
a plurality of nanosheets spaced apart from each other in the third direction on the first active pattern;
a fin-shaped pattern spaced apart from the plurality of nanosheets in the second direction, the fin-shaped pattern comprising a first portion spaced apart from the second active pattern in the third direction and a second portion being in contact with an upper surface of the first portion, wherein a width in the second direction of a bottom surface of the second portion is greater than a width in the second direction of the upper surface of the first portion;
a first gate electrode extending in the second direction on the first active pattern, the first gate electrode at least partially surrounding the plurality of nanosheets;
a second gate electrode extending in the second direction on the second active pattern, the second gate electrode being spaced apart from the first gate electrode in the second direction, the second gate electrode at least partially surrounding the fin-shaped pattern, and at least a portion of the second gate electrode being between the upper surface of the second active pattern and a bottom surface of the fin-shaped pattern;
a first gate insulating layer between the first gate electrode and the plurality of nanosheets; and
a second gate insulating layer between the second gate electrode and the fin-shaped pattern,
wherein a thickness of the second gate insulating layer is greater than a thickness of the first gate insulating layer,
wherein a thickness in the third direction of the second portion of the fin-shaped pattern is the same as a thickness in the third direction of an uppermost nanosheet of the plurality of nanosheets, and
wherein an upper surface of the fin-shaped pattern is on the same plane as an upper surface of the uppermost nanosheet of the plurality of nanosheets.
